(19) United States
(12) Patent Application Publication
(10) Pub. No.: US 2024/0429254 A1
(43) Pub. Date: Dec. 26, 2024

(54) IMAGING DEVICE

(71) Applicant: SONY SEMICONDUCTOR SOLUTIONS CORPORATION, KANAGAWA (JP)

(72) Inventors: SHINICHIRO NOUDO, KANAGAWA (JP); KAITO YOKOCHI, KANAGAWA (JP); KOJI SEKIGUCHI, KANAGAWA (JP); ATSUSHI TODA, KANAGAWA (JP)

(21) Appl. No.: 18/687,167

(22) PCT Filed: Mar. 17, 2022
(86) PCT No.: PCT/JP2022/012409

§ 371 Date: Feb. 27, 2024

(30) Foreign Application Priority Data
Sep. 16, 2021 (JP) 2021-150995

(51) Int. Cl. H01L 27/146

(52) U.S. Cl. CPC H01L 27/14621; H01L 27/1462; H01L 27/14623; H01L 27/14645; H01L 27/14685

(57) ABSTRACT

An imaging device according to an embodiment of the present disclosure includes: a semiconductor substrate having a first surface and a second surface that are opposed to each other, and including a plurality of pixels and a plurality of photoelectric converters, the plurality of pixels disposed in a matrix, and the plurality of photoelectric converters that generates, through photoelectric conversion, an electric charge corresponding to an amount of received light incident from a subject without passing through an on-chip lens for each of the pixels; a plurality of color filters provided one for each of the plurality of pixels on side of the first surface; a first protective film that covers top surfaces and side surfaces of the plurality of color filters; a gap section provided between the plurality of respective color filters; and a light-blocking section provided at a bottom of the gap section.

### TECHNICAL FIELD

The present disclosure relates to an imaging device.

### BACKGROUND ART

For example, PTL 1 discloses an imaging device in which a first light transmissive film having a first refractive index, and a second light transmissive film having a second refractive index higher than the first refractive index are stacked in order on a color filter provided on each of a plurality of pixels.

### CITATION LIST

### Patent Literature

PTL 1: International Publication No. WO2020/158443

### SUMMARY OF THE INVENTION

Incidentally, an imaging device is desired to achieve both an improvement in sensitivity and reduction in occurrence of color mixture.

It is desirable to provide an imaging device that makes it possible to reduce occurrence of color mixture while improving sensitivity.

An imaging device according to an embodiment of the present disclosure includes: a semiconductor substrate having a first surface and a second surface that are opposed to each other, and including a plurality of pixels and a plurality of photoelectric converters, the plurality of pixels disposed in a matrix, and the plurality of photoelectric converters that generates, through photoelectric conversion, an electric charge corresponding to an amount of received light incident from a subject without passing through an on-chip lens for each of the pixels; a plurality of color filters provided one for each of the plurality of pixels on side of the first surface; a first protective film that covers top surfaces and side surfaces of the plurality of color filters; a gap section provided between the plurality of respective color filters; and a light-blocking section provided at a bottom of the gap section.

In the imaging device according to the embodiment of the present disclosure, the plurality of color filters is provided one for each of the plurality of pixels, the gap section is provided between the respective color filters, and the light-blocking section is formed at the bottom of the gap section. Accordingly, the light incident from the subject without passing through the on-chip lens is reflected at the interface between the color filters and the gap section, and absorption in the light-blocking section is reduced. Further, the first protective film that covers the top surfaces and the side surfaces of the plurality of color filters is provided. This suppresses discoloration of the color filters.

### BRIEF DESCRIPTION OF DRAWINGS

FIG. 1 is a schematic cross-sectional view of a configuration example of an imaging device according to an embodiment of the present disclosure.

FIG. 2 is a block diagram illustrating an entire configuration of the imaging device illustrated in FIG. 1.

FIG. 3 is an equivalent circuit diagram of a unit pixel illustrated in FIG. 1.

FIG. 4 is a schematic view of an example of a shape of a lower portion of a color filter illustrated in FIG. 1.

FIG. 5A is a schematic cross-sectional view for describing a method of manufacturing the imaging device illustrated in FIG. 1.

FIG. 5B is a cross-sectional view of a process subsequent to FIG. 5A.

FIG. 5C is a cross-sectional view of a process subsequent to FIG. 5B.

FIG. 5D is a cross-sectional view of a process subsequent to FIG. 5C.

FIG. 5E is a cross-sectional view of a process subsequent to FIG. 5D.

FIG. 5F is a cross-sectional view of a process subsequent to FIG. 5E.

FIG. 5G is a cross-sectional view of a process subsequent to FIG. 5F.

FIG. 5H is a cross-sectional view of a process subsequent to FIG. 5G.

FIG. 6 is a light intensity distribution diagram in an optical simulation of an imaging device as a comparative example.

FIG. 7 is a light intensity distribution diagram in an optical simulation of the imaging device illustrated in FIG. 1.

FIG. 8 is a characteristic diagram illustrating results of quantum efficiencies at respective wavelengths by optical simulations of the respective imaging devices illustrated in FIG. 1 and FIG. 6.

FIG. 9 is a schematic cross-sectional view of a configuration example of an imaging device according to a modification example 1 of the present disclosure.

FIG. 10 is a schematic cross-sectional view of a configuration example of an imaging device according to a modification example 2 of the present disclosure.

FIG. 11A is a schematic cross-sectional view for describing another example of the method of manufacturing the imaging device illustrated in FIG. 1.

FIG. 11B is a cross-sectional view of a process subsequent to FIG. 11A.

FIG. 11C is a cross-sectional view of a process subsequent to FIG. 11B.

FIG. 12A is a schematic cross-sectional view for describing another example of the method of manufacturing the imaging device illustrated in FIG. 1.

FIG. 12B is a cross-sectional view of a process subsequent to FIG. 12A.

FIG. 12C is a cross-sectional view of a process subsequent to FIG. 12B.

FIG. 13A is a schematic cross-sectional view for describing another example of the method of manufacturing the imaging device illustrated in FIG. 1.

FIG. 13B is a cross-sectional view of a process subsequent to FIG. 13A.

FIG. 13C is a cross-sectional view of a process subsequent to FIG. 13B.

FIG. 13D is a cross-sectional view of a process subsequent to FIG. 13C.

FIG. 13E is a cross-sectional view of a process subsequent to FIG. 13D.

FIG. 14 is a schematic cross-sectional view of an example of a configuration of an imaging device according to a modification example 6 of the present disclosure.

FIG. 15 is a schematic cross-sectional view of another example of the configuration of the imaging device according to the modification example 6 of the present disclosure.

FIG. 16 is a schematic cross-sectional view of another example of the configuration of the imaging device according to the modification example 6 of the present disclosure.

FIG. 17 is a schematic cross-sectional view of another example of the configuration of the imaging device according to the modification example 6 of the present disclosure.

FIG. 18 is a schematic cross-sectional view of an example of a configuration of an imaging device according to a modification example 7 of the present disclosure.

FIG. 19A is a schematic cross-sectional view for describing a method of manufacturing the imaging device illustrated in FIG. 18.

FIG. 19B is a cross-sectional view of a process subsequent to FIG. 19A.

FIG. 19C is a cross-sectional view of a process subsequent to FIG. 19B.

FIG. 19D is a cross-sectional view of a process subsequent to FIG. 19C.

FIG. 19E is a cross-sectional view of a process subsequent to FIG. 19D.

FIG. 19F is a cross-sectional view of a process subsequent to FIG. 19E.

FIG. 19G is a cross-sectional view of a process subsequent to FIG. 19F.

FIG. 19H is a cross-sectional view of a process subsequent to FIG. 19G.

FIG. 20 is a schematic cross-sectional view of another example of the configuration of the imaging device according to the modification example 7 of the present disclosure.

FIG. 21 is a schematic cross-sectional view of a configuration example of an imaging device according to a modification example 8 of the present disclosure.

FIG. 22A is a schematic plan view of an example of a pixel arrangement in an imaging device according to a modification example 9 of the present disclosure.

FIG. 22B is a schematic plan view of another example of the pixel arrangement in the imaging device according to the modification example 9 of the present disclosure.

FIG. 23 is a schematic cross-sectional view of an example of a configuration of the imaging device according to the modification example 9 of the present disclosure.

FIG. 24 is a schematic cross-sectional view of another example of the configuration of the imaging device according to the modification example 9 of the present disclosure.

FIG. 25 is a schematic cross-sectional view of an example of a configuration of an imaging device according to a modification example 10 of the present disclosure.

FIG. 26 is a schematic cross-sectional view of another example of the configuration of the imaging device according to the modification example 10 of the present disclosure.

FIG. 27A is a characteristic diagram with respect to oblique incidence in the imaging device illustrated in FIG. 25.

FIG. 27B is a characteristic diagram with respect to oblique incidence in the imaging device illustrated in FIG. 26.

FIG. 28 is a schematic plan view of an example of a pixel configuration of an imaging device according to a modification example 11 of the present disclosure.

FIG. 29 is a schematic cross-sectional view of an example of a configuration of the imaging device illustrated in FIG. 28.

FIG. 30 is a schematic cross-sectional view of another example of the configuration of the imaging device illustrated in FIG. 28.

FIG. 31 is a schematic cross-sectional view of another example of the configuration of the imaging device illustrated in FIG. 28.

FIG. 32 is a schematic plan view of an example of a pixel configuration of an imaging device according to a modification example 12 of the present disclosure.

FIG. 33 is a schematic cross-sectional view of an example of a configuration of the imaging device illustrated in FIG. 32.

FIG. 34 is a schematic cross-sectional view of another example of the configuration of the imaging device illustrated in FIG. 32.

FIG. 35 is a schematic cross-sectional view of another example of the configuration of the imaging device illustrated in FIG. 32.

FIG. 36 is a schematic cross-sectional view of another example of the configuration of the imaging device illustrated in FIG. 32.

FIG. 37 is a schematic cross-sectional view of another example of the configuration of the imaging device illustrated in FIG. 32.

FIG. 38 is a schematic cross-sectional view of a configuration example of an imaging device according to a modification example 13 of the present disclosure.

FIG. 39 is a block diagram illustrating a configuration example of an electronic apparatus including the imaging device illustrated in FIG. 1 or the like.

FIG. 40A is a schematic view of an example of an entire configuration of a photodetection system using the imaging device illustrated in FIG. 1 or the like.

FIG. 40B is a diagram illustrating an example of a circuit configuration of the photodetection system illustrated in FIG. 40A.

FIG. 41 is a view depicting an example of a schematic configuration of an endoscopic surgery system.

FIG. 42 is a block diagram depicting an example of a functional configuration of a camera head and a camera control unit (CCU).

FIG. 43 is a block diagram depicting an example of schematic configuration of a vehicle control system.

FIG. 44 is a diagram of assistance in explaining an example of installation positions of an outside-vehicle information detecting section and an imaging section.

### MODES FOR CARRYING OUT THE INVENTION

Some embodiments of the present disclosure are described below in detail with reference to the drawings. The following description is a specific example of the present disclosure, and the present disclosure is not limited to the following embodiments. In addition, the present disclosure is not limited to arrangements, dimensions, dimension ratios, etc. of respective components illustrated in each drawing. It is to be noted that description is given in the following order.
1. Embodiment (An example of an imaging device having a gap section between adjacent color filters)
2. Modification Examples
2-1. Modification Example 1 (An example in which color filters that absorb light in wavelength bands different from each other are stacked)
2-2. Modification Example 2 (An example of an imaging device including a color filter that has a top surface having a curved shape)
2-3. Modification Example 3 (Another example of a method of manufacturing the imaging device)
2-4. Modification Example 4 (Another example of the method of manufacturing the imaging device)
2-5. Modification Example 5 (Another example of the method of manufacturing the imaging device)
2-6. Modification Example 6 (Another example of a structure of an element isolator)
2-7. Modification Example 7 (Another example of a formation position and a shape of a light-blocking section)
2-8. Modification Example 8 (Another example of a configuration of the imaging device)
2-9. Modification Example 9 (Another example of the configuration of the imaging device)
2-10. Modification Example 10 (A configuration example of an image-plane phase-difference pixel)
2-11. Modification Example 11 (A configuration example of the image-plane phase-difference pixel)
2-12. Modification Example 12 (A configuration example of the image-plane phase-difference pixel)
2-13. Modification Example 13 (An example in which an upper end of the gap section is blocked by a protective film)
3. Application Examples
4. Practical Application Examples

### 1. EMBODIMENT

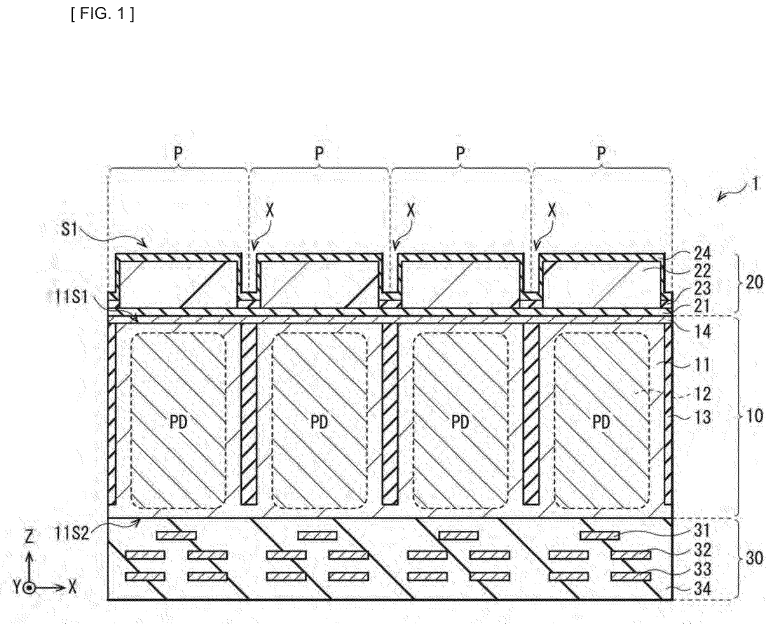

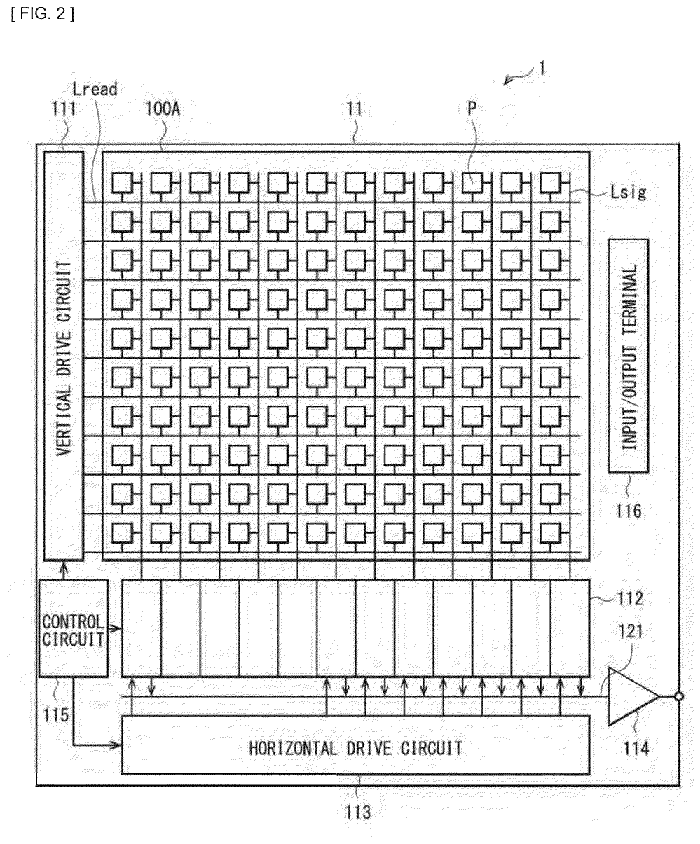

FIG. 1 schematically illustrates an example of a cross-sectional configuration of an imaging device (an imaging device 1) according to an embodiment of the present disclosure. FIG. 2 illustrates an example of an entire configuration of the imaging device 1 illustrated in FIG. 1. The imaging device 1 is, for example, a CMOS (Complementary Metal Oxide Semiconductor) image sensor or the like used for an electronic apparatus such as a digital still camera or a video camera, and includes, as an imaging area, a pixel section (a pixel section 100A) in which a plurality of pixels is two-dimensionally disposed in a matrix. The imaging device 1 is, for example, what is called a back-illuminated imaging device in this CMOS image sensor or the like.

The imaging device 1 includes, for example, a plurality of color filters 22 provided one for each of a plurality of unit pixels P disposed in a matrix with a pitch of 1.5 μm or less. In the imaging device 1 according to the present embodiment, each of the plurality of color filters 22 is provided one for each of the unit pixels P, and a gap section X is formed between the respective color filters 22. A light-blocking section 23 is provided at a bottom of the gap section X. Further, top surfaces and side surfaces of the plurality of color filters 22 are covered with a protective film 24.

### Schematic Configuration of Imaging Device

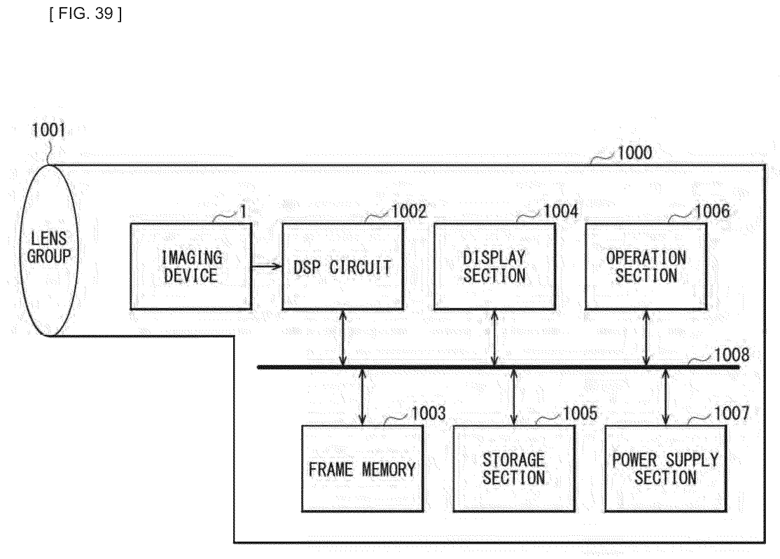

The imaging device 1 takes in incident light (image light) from a subject through an optical lens system (e.g., a lens group 1001, see FIG. 39). The imaging device 1 converts the light amount of incident light of which an image is formed on an imaging plane into an electric signal for each pixel unit P, and outputs the electric signal as a pixel signal. The imaging device 1 includes the pixel section 100A serving as the imaging area on the semiconductor substrate 11, and includes, for example, a vertical drive circuit 111, a column signal processing circuit 112, a horizontal drive circuit 113, an output circuit 114, a control circuit 115, and an input/output terminal 116 in a peripheral region of this pixel section 100A.

The pixel section 100A includes, for example, the plurality of unit pixels P that is two-dimensionally disposed in a matrix. The plurality of unit pixels P each photoelectrically converts, in a photodiode PD, a subject image formed by an imaging lens to generate a signal for image generation.

The unit pixels P are wired with pixel drive lines Lread (specifically, row selection lines and reset control lines) for respective pixel rows, and are wired with vertical signal lines Lsig for respective pixel columns. The pixel drive lines Lread transmits drive signals for signal reading from the pixels. The pixel drive lines Lread each have one end coupled to a corresponding one of output ends, corresponding to the respective rows, of the vertical drive circuit 111.

The vertical drive circuit 111 includes a shift register, an address decoder, and the like, and is a pixel driver that drives the respective unit pixels P of the pixel section 100A, for example, on a row-by-row basis. The signals outputted from the respective unit pixels P in the pixel rows selectively scanned by the vertical drive circuit 111 are supplied to the column signal processing circuits 112 through the respective vertical signal lines Lsig. Each of the column signal processing circuits 112 includes an amplifier, a horizontal selection switch, and the like that are provided for each of the vertical signal lines Lsig.

The horizontal drive circuit 113 includes a shift register, an address decoder, and the like, and drives the respective horizontal selection switches of the column signal processing circuits 112 in order while scanning the horizontal selection switches. This selective scanning by the horizontal drive circuit 113 causes the signals of the respective pixels transmitted through the respective vertical signal lines Lsig to be outputted in sequence to a horizontal signal line 121 and transmitted to outside of the semiconductor substrate 11 through the horizontal signal line 121.

The output circuit 114 performs signal processing on the signals sequentially supplied from the respective column signal processing circuits 112 through the horizontal signal line 121 and outputs the signals. The output circuit 114 performs, for example, only buffering in some cases and performs black level adjustment, column variation correction, various kinds of digital signal processing, and the like in other cases.

Circuit portions including the vertical drive circuit 111, the column signal processing circuits 112, the horizontal drive circuit 113, the horizontal signal line 121, and the output circuit 114 may be formed directly on the semiconductor substrate 11 or may be provided in an external control IC. Alternatively, those circuit portions may be formed on any other substrate coupled by a cable or the like.

The control circuit 115 receives a clock given from the outside of the semiconductor substrate 11, data for an instruction about an operation mode, and the like, and also outputs data such as internal information of the imaging device 1. The control circuit 115 further includes a timing generator that generates various timing signals, and performs drive control of peripheral circuits such as the vertical drive circuit 111, the column signal processing circuit 112, and the horizontal drive circuit 113 on the basis of the various timing signals generated by the timing generator.

The input/output terminal 116 exchanges signals with the outside.

### Circuit Configuration of Unit Pixel

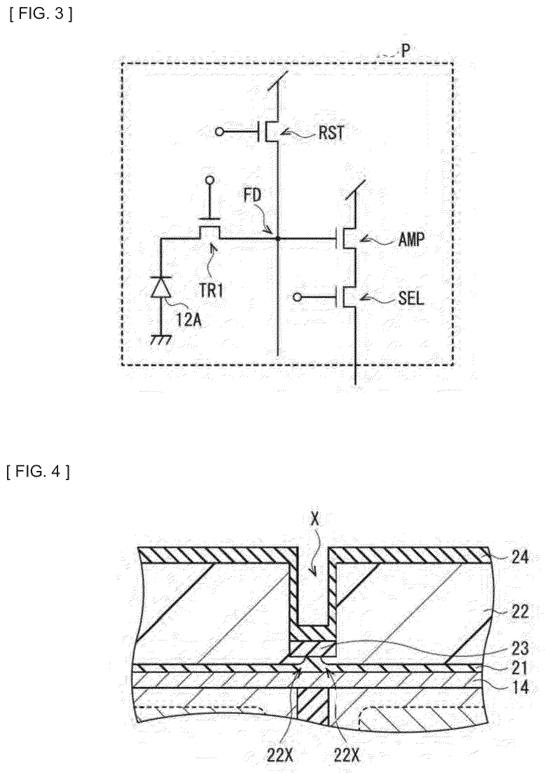

FIG. 3 illustrates an example of a readout circuit of the unit pixel P of the imaging device 1 illustrated in FIG. 2. The unit pixel P includes, for example, one photoelectric converter 12, a transfer transistor TR, a floating diffusion FD, a reset transistor RST, an amplification transistor AMP, and a selection transistor SEL, as illustrated in FIG. 3.

The photoelectric converter 12 is a photodiode (PD). The photoelectric converter 12 has an anode coupled to a ground voltage line, and a cathode coupled to a source of the transfer transistor TR1.

The transfer transistor TR1 is coupled between the photoelectric converter 12 and the floating diffusion FD. A drive signal TRsig is applied to a gate electrode of the transfer transistor TR. In a case where this drive signal TRsig is turned to an active state, a transfer gate of the transfer transistor TR is turned to an electrically conductive state, and a signal electric charge accumulated in the photoelectric converter 12 is transferred to the floating diffusion FD through the transfer transistor TR.

The floating diffusion FD is coupled between the transfer transistor TR and the amplification transistor AMP. The floating diffusion FD converts the signal electric charge transferred by the transfer transistor TR into a voltage signal through electric charge-voltage conversion, and outputs the voltage signal to the amplification transistor AMP.

The reset transistor RST is coupled between the floating diffusion FD and a power supply section. A drive signal RSTsig is applied to a gate electrode of the reset transistor RST. In a case where the drive signal RSTsig is turned to the active state, a reset gate of the reset transistor RST is turned to the electrically conductive state, and a potential of the floating diffusion FD is reset to a level of the power supply section.

The amplification transistor AMP has a gate electrode coupled to the floating diffusion FD, and a drain electrode coupled to the power supply section, and serves as an input section of a readout circuit for a voltage signal held by the floating diffusion FD, that is, what is called a source follower circuit. In other words, the amplification transistor AMP has a source electrode coupled to the vertical signal line Lsig through the selection transistor SEL, thereby configuring a source follower circuit with a constant current source coupled to one end of the vertical signal line Lsig.

The selection transistor SEL is coupled between the source electrode of the amplification transistor AMP and the vertical signal line Lsig. A drive signal SELsig is applied to a gate electrode of the selection transistor SEL. In a case where the drive signal SELsig is turned to the active state, the selection transistor SEL is turned to the electrically conductive state to turn the unit pixel P to a selected state. Accordingly, a readout signal (a pixel signal) outputted from the amplification transistor AMP is outputted to the vertical signal line Lsig through the selection transistor SEL.

### Configuration of Unit Pixel

The imaging device 1 is, for example, a back-illuminated imaging device as described above, and the plurality of unit pixels P two-dimensionally disposed in a matrix in the pixel section 100A each has, for example, a configuration in which a light-receiving section 10, a light-condensing section 20, and a multilayer wiring layer 30 are stacked. The light-condensing section 20 is provided on light incident side S1 of the light-receiving section 10. The multilayer wiring layer 30 is provided on side opposite to the light incident side S1 of the light-receiving section 10.

The light-receiving section 10 includes the semiconductor substrate 11 and a plurality of photoelectric converters 12. The semiconductor substrate 11 has a first surface 11S1 and a second surface 11S2 opposed to each other. The plurality of photoelectric converters 12 is formed so as to be embedded in the semiconductor substrate 11. The semiconductor substrate 11 includes, for example, a silicon substrate. Each of the photoelectric converters 12 is, for example, a PIN (Positive Intrinsic Negative) type photodiode (PD), and includes a pn junction in a predetermined region of the semiconductor substrate 11. As described above, the photoelectric converters 12 are formed so as to be embedded in the unit pixels P.

The light-receiving section 10 further includes an element isolator 13.

The element isolator 13 is provided between adjacent unit pixels P. In other words, the element isolator 13 is provided around the unit pixels P, and is provided, for example, in a lattice form in the pixel section 100A. The element isolator 13 is provided to electrically and optically isolate adjacent unit pixels P from each other. The element isolator 13 extends, for example, from side of the first surface 11S1 of the semiconductor substrate 11 toward side of the second surface 11S2. It is possible to form the element isolator 13, for example, by diffusing a p-type impurity.

A fixed electric charge layer 14 is further provided on the first surface 11S1 of

the semiconductor substrate 11. The fixed electric charge layer 14 also serves to prevent reflection at the first surface 11S1 of the semiconductor substrate 11. The fixed electric charge layer 14 includes, for example, a film having a negative fixed electric charge. As a constituent material of the fixed electric charge layer 14 is a semiconductor material or an electrically conductive material having a band gap wider than a band gap of the semiconductor substrate 11. Specific examples of the semiconductor material and the electrically conductive material include hafnium oxide (HfOₓ), aluminum oxide (AlOₓ), zirconium oxide (ZrOₓ), tantalum oxide (TaOₓ), titanium oxide (TiOₓ), lanthanum oxide (LaOₓ), praseodymium oxide (PrOₓ), cerium oxide (CeOₓ), neodymium oxide (NdOₓ), promethium oxide (PmOₓ), samarium oxide (SmOₓ), europium oxide (EuOₓ), gadolinium oxide (GdOₓ), terbium oxide (TbOₓ), dysprosium oxide (DyOₓ), holmium oxide (HoOₓ), thulium oxide (TmOₓ), ytterbium oxide (YbOₓ), lutetium oxide (LuOₓ), yttrium oxide (YOₓ), hafnium nitride (HfNₓ), aluminum nitride (AlNₓ), hafnium oxynitride (HfOₓN_{y}), aluminum oxynitride (AlOₓN_{y}), and the like. The fixed electric charge layer 14 may be a single-layer film, or may be a stacked film including different materials.

The light-condensing section 20 is provided on the light incident side S1 of the light-receiving section 10, and includes, for example, an insulating layer 21, and the color filters 22 provided for the respective unit pixels P, and the light-blocking section 23. The color filters 22 each allow, for example, red light (R), green light (G), or blue light (B) to selectively pass therethrough. The light-blocking section 23 is provided between the unit pixels P of the color filters 22. The light-condensing section 20 further includes the protective film 24 that covers the top surfaces and the side surfaces of the color filters 22 and a top surface of the light-blocking section 23.

The insulating layer 21 is provided to reduce deterioration in dark time characteristics. The insulating layer 21 is provided, for example, on the fixed electric charge layer 14. In addition, a refractive index and a film thickness of a material of the insulating layer 21 are appropriately set, which allows the insulating layer 21 to suppress reflection of light generated by a refractive index difference between the semiconductor substrate 11 and the color filters 22. As a constituent material of the insulating layer 21, a material having a refractive index lower than that of the fixed electric charge layer 14 is preferable. Examples thereof include SiOₓ, SiNₓ, and SiOₓN_{y}, and the like.

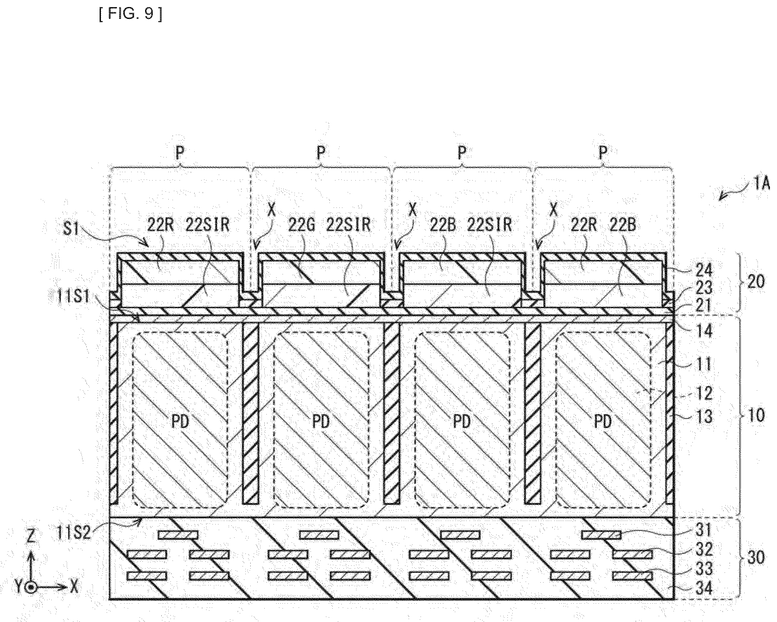

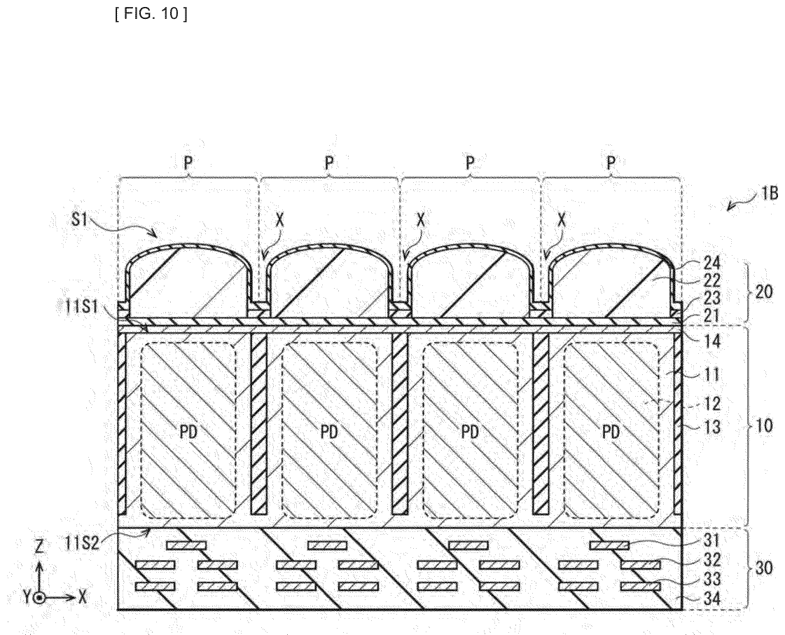

The color filters 22 each allow light having a predetermined wavelength to selectively pass therethrough. The color filters 22 include, for example, a color filter 22G, a color filter 22R, and a color filter 22B (for example, see FIG. 9). The color filter 22R allows the red light (R) to selectively pass therethrough. The color filter 22G allows the green light (G) to selectively pass therethrough. The color filter 22B allows the blue light (B) to selectively pass therethrough. The color filters 22 may further include filters that each allow a corresponding one of cyan, magenta, and yellow to selectively pass therethrough. In the unit pixels P each provided with a corresponding one of the color filters 22R, 22G, and 22B, for example, light of a corresponding color is detected in a corresponding one of the photoelectric converters 12. It is possible to form the color filters 22 with use of, for example, a pigment or a dye. The film thicknesses of the color filters 22 may differ for each color in consideration of color reproducibility and sensor sensitivity by a spectral spectrum thereof. It is to be noted that it is possible to regard a layer including a transparent material as the color filter 22 in a black-and-white pixel. It is possible to regard a layer including a material that allows an infrared ray to selectively pass therethrough as the color filter 22 in a pixel for the infrared ray.

In the present embodiment, the color filters 22 are provided one for each of the unit pixels P, and the gap section X is formed between the adjacent color filters 22. In other words, the gap section X is formed, for example, between the adjacent unit pixels P, and is provided, for example, in a lattice form in the pixel section 100A. The color filters 22 obtain a light-condensing effect (a lens function) by a light phase shift caused by a refractive index difference between the color filters 22 and the gap section X. Accordingly, the color filters 22 preferably have, for example, a refractive index of 1.4 or more. Forming the color filters 22 by adding, for example, TiOₓ makes it possible to increase the refractive indices of the color filters 22. It is to be noted that in order to allow the color filters 22 to exert a desired lens effect, a pixel pitch of 1.5 μm or less is desirable. In order to exert the light-condensing effect, a wavefront is desired to be wave-optically bent in the gap section X; however, in a case where a pixel size increases, a light-ray tracking behavior is exhibited, which prevents the desired lens effect from being exerted.

FIG. 4 schematically illustrates an example of a shape of a lower portion of the color filter 22. As illustrated in FIG. 4, the color filter 22 may have an overhang portion 22X extending toward a bottom of the light-blocking section 23. Accordingly, an anchor effect caused by the overhang portion 22X makes it possible to reduce film peeling of the color filter 22. For example, the insulating layer 21 is isotropically etched by wet etching after formation of the light-blocking section 23, and thereafter, in formation of the color filter 22 by coating, the color filter 22 is cured in a state in which the color filter 22 extends to the bottom of the light-blocking section 23, thus making it possible to form the overhang portion 22X.

The light-blocking section 23 is provided to prevent leakage of light having obliquely entered the color filter 22 to the adjacent unit pixels P. As described above, the light-blocking section 23 is provided at the bottom of the gap section X. In other words, the light-blocking section 23 is provided, for example, in a lattice form in the pixel section 100A similarly to the gap section X.

Examples of a material included in the light-blocking section 23 include a material having a light-blocking property. Specific examples thereof include tungsten (W), silver (Ag), copper (Cu), titanium (Ti), aluminum (Al), and alloys thereof. The examples further include a metal compound such as TiN. The light-blocking section 23 may be formed, for example, as a single-layer film or a stacked film. In a case where the light-blocking section 23 is formed as a stacked film, for example, a layer including Ti, tantalum (Ta), W, cobalt (Co), molybdenum (Mo), or an alloy thereof, a nitride thereof, an oxide thereof, or a carbide thereof may be provided as a base layer in order to enhance adhesion to the insulating layer 21.

The light-blocking section 23 may also serve as light blocking for the unit pixel P that determines an optical black level. In addition, the light-blocking section 23 may also serve as light blocking for suppressing generation of noise to a peripheral circuit provided in the peripheral region of the pixel section 100A. The light-blocking section 23 is preferably grounded so as not to be destroyed by plasma damage caused by accumulated electric charges during processing. As described in detail later, a grounding structure may be provided in the pixel section 100A, or may be provided in the peripheral region so as to electrically couple the entire light-blocking section 23 provided throughout the pixel section 100A.

The protective film 24 is provided to protect the color filters 22. The protective film 24 is provided to cover, for example, the top surfaces and the side surfaces of the color filters 22. The protective film 24 may further cover the top surface of the light-blocking section 23. The protective film 24 is provided, for example, to suppress entry of oxygen from an external environment and prevent discoloration of the color filters 22 caused by photooxidation. Further, providing the protective film 24 makes it possible to enhance mechanical strength. In a case where the light-blocking section 23 is covered with the protective film 24, the protective film 24 also serves as a passivation film for the light-blocking section 23. It is possible to form the protective film 24 with use of a material having a refractive index lower than that of the color filters 22. As such a material, for example, SiOₓ, SiNₓ, and SiOₓN_{y}, and an inorganic material such as magnesium fluoride (MgF₂) is suitable. In addition, for the protective film 24, it is possible to use SiOₓ containing air bubbles, which is called porous silica or hollow silica, or a resin material including a low refractive index material.

A film thickness of the protective film 24 on the top surfaces is, for example, a λ/4n with respect to a wavelength λ to be detected and a refractive index n of the protective film 24, which makes it possible to additionally have a reflection prevention function. For example, in a case where a wavelength in a visible region is detected in the unit pixel P, and the protective film 24 is formed with use of SiO₂, the film thickness of the protective film 24 is preferably from 70 nm to 130 nm, more preferably from 90 nm to 120 nm. It is to be noted that the film thickness of the protective film 24 depends on the detected wavelength μ, and an optimum film thickness thereof differs; therefore, the film thickness may be formed separately for each unit pixel P. For example, in a case where the protective film 24 is formed with use of SiO₂, the film thickness thereof is preferably from 100 nm to 120 nm for the unit pixel P (a red pixel Pr) that detects the red light (R), is preferably 80 nm to 100 nm for the unit pixel P (a red pixel Pr) that detects the green light (G), and is preferably from 70 nm to 90 nm for the unit pixel P (a red pixel Pr) that detects the blue light (B).

In addition, in the present embodiment, incident light is condensed to the photoelectric converter 12 by a light phase shift caused by a refractive index difference between the color filters 22 and the gap section X; therefore, the protective film 24 that covers the side surfaces of the color filters 22 is preferably formed thinner than the protective film 24 that covers the top surfaces of the color filters 22.

The protective film 24 may be formed as a stacked film including different materials. The protective film 24 is, for example, a stacked film including an insulating film having a high refractive index and an insulating film having a low refractive index that are stacked in this order, which makes it possible to enhance a reflection prevention effect for color filters. It is possible to form the insulating film having a high refractive index with use of, for example, a material having a refractive index of 1.8 to 2.5 such as silicon nitride (Si₃N₄), titanium oxide (TiO₂), tantalum oxide (Ta₂O₅), zirconium oxide (ZrO₂), niobium oxide (Nb₂O₅), hafnium oxide (HfO₂), or aluminum oxide (Al₂O₃). It is possible to form the insulating film having a low refractive index with use of, for example, a material such as SiO₂, SiON, or SiOC.

The multilayer wiring layer 30 is provided on side opposite to the light incident side S1 of the light-receiving section 10. Specifically, the multilayer wiring layer 30 is provided on side of the second surface 11S2 of the semiconductor substrate 11. The multilayer wiring layer 30 has a configuration in which a plurality of wiring layers 31, 32, and 33 is stacked with an interlayer insulating layer 34 interposed therebetween. In addition to the readout circuit described above, the vertical drive circuit 111, the column signal processing circuit 112, the horizontal drive circuit 113, the output circuit 114, the control circuit 115, the input/output terminal 116, and the like are formed on the multilayer wiring layer 30, for example.

The wiring layers 31, 32, and 33 are formed with use of, for example, aluminum (Al), copper (Cu), tungsten (W), or the like. The wiring layers 31, 32, and 33 may be formed with use of polysilicon (poly-Si) other than these materials.

For example, the interlayer insulating layer 34 includes a single-layer film including one kind from among silicon oxide (SiOₓ), silicon nitride (SiNₓ), silicon oxynitride (SiOₓN_{y}), and the like, or includes a stacked film including two or more kinds from among these materials.

### Method of Manufacturing Inter-pixel Isolator and In-pixel Isolator

It is possible to manufacture the imaging device 1 as follows, for example.

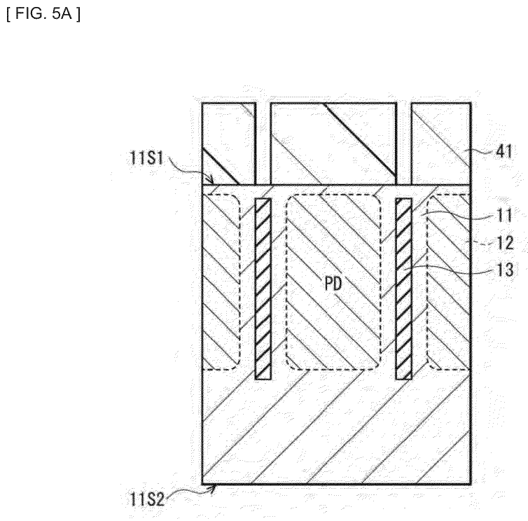

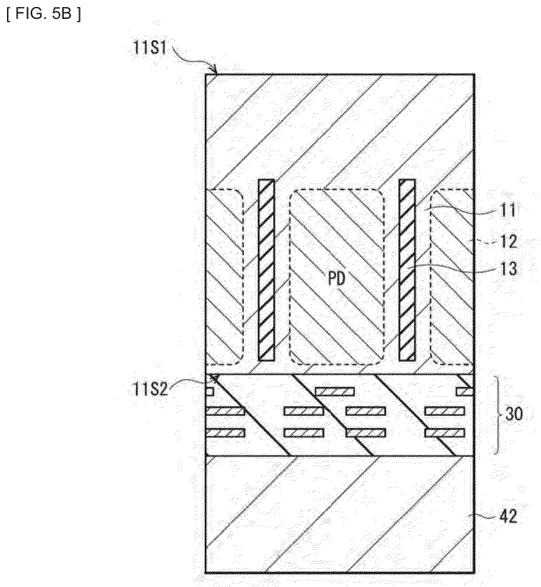

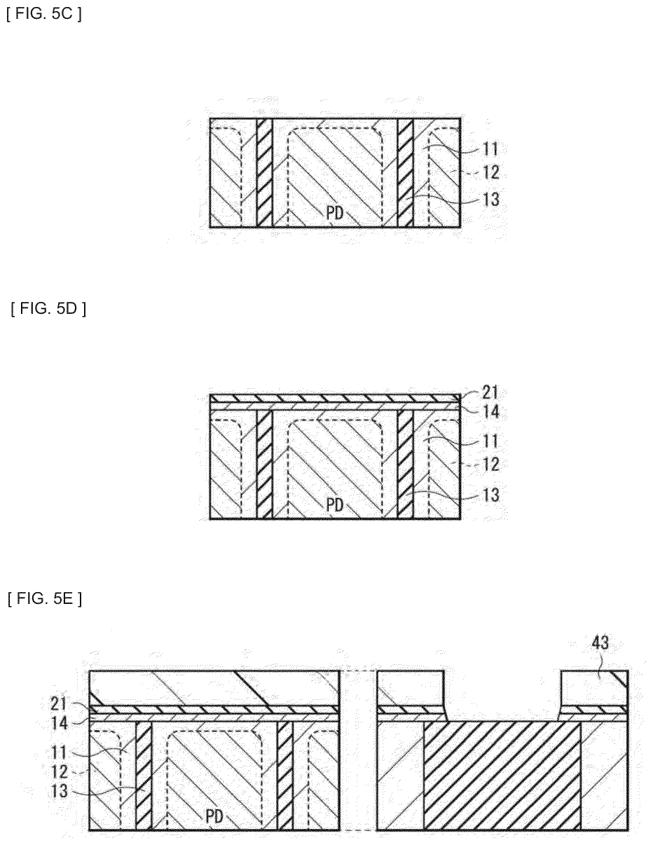

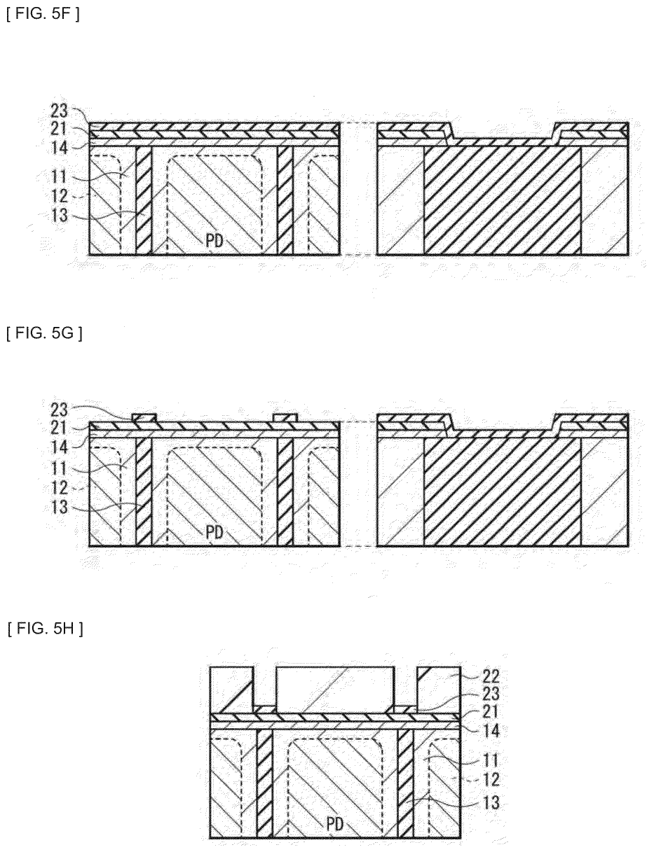

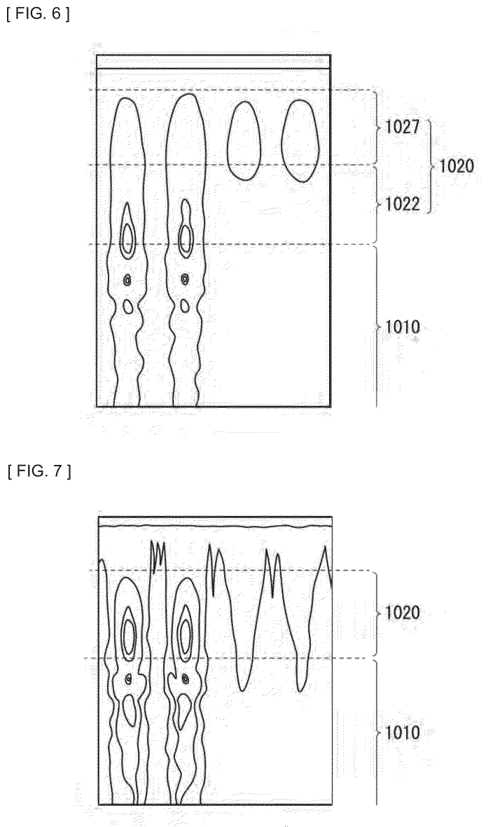

First, as illustrated in FIG. 5A, after a resist 41 is patterned on the second surface 11S2 of the semiconductor substrate 11 on which the photoelectric converters 12 is provided for each unit pixel P, the element isolator 13 is formed by ion implantation using the resist 41 as a mask. Thereafter, the resist 41 is removed, and pixel transistors such as the transfer transistor TR, the floating diffusion FD, the reset transistor RST, the amplification transistor AMP, and the selection transistor SEL are formed on the second surface 11S2 of the semiconductor substrate 11 (not illustrated).

Subsequently, the multilayer wiring layer 30 is formed on the second surface 11S2 of the semiconductor substrate 11. Thereafter, as illustrated in FIG. 5B, a support substrate 42 is joined onto the semiconductor substrate 11, and the semiconductor substrate 11 is flipped. Next, as illustrated in FIG. 5C, the semiconductor substrate 11 is polished from side of the first surface 11S1 of the semiconductor substrate 11 with use of, for example, wet etching, dry etching, or chemical mechanical polishing (CMP) to be thinned.

Next, as illustrated in FIG. 5D, the fixed electric charge layer 14 and the insulating layer 21 are formed in order on the first surface 11S1 of the semiconductor substrate 11 with use of, for example, a chemical vapor deposition (CVD) method, sputtering, an atomic layer deposition (ALD) method, or the like.

Subsequently, the light-blocking section 23 is formed with use of, for example, a CVD method, sputtering, or the like. At this time, in a case where the light-blocking section 23 is formed with use of a metal material, there is a possibility that plasma damage is caused by processing a metal film in an electrically floating state. Accordingly, as illustrated in FIG. 5E, the resist 43 is patterned on the light-blocking section 23, and as illustrated in a right diagram in FIG. 5E, for example, the fixed electric charge layer 14 and the insulating layer 21 are etched to expose the first surface 11S1 of the semiconductor substrate 11 in the peripheral region. Thereafter, as illustrated in FIG. 5F, the light-blocking section 23 is formed. Accordingly, as illustrated in a right diagram in FIG. 5F, the light-blocking section 23 is formed on the first surface 11S1 of the semiconductor substrate 11 in the peripheral region. For example, a p-type semiconductor region 13X to which a ground (GND) potential is to be applied is preferably formed in the semiconductor substrate 11 on which the light-blocking section 23 is formed.

Next, as illustrated in FIG. 5G, the light-blocking section 23 is patterned into a desired shape by, for example, anisotropic etching or the like. At this time, a residue of the light-blocking section 23 is removed by chemical cleaning, as necessary. Subsequently, as illustrated in FIG. 5H, for example, a resist including a photosensitizing agent and a pigment is spin-coated, and is exposed, developed, and post-baked to form the color filters 22. In a case where the color filters 22 are formed with use of the resist including the photosensitizing agent and the pigment, UV curing or additional baking may be performed.

Thereafter, the protective film 24 is formed with use of, for example, sputtering. At this time, adopting a long-throw condition in which a target position in a sputtering device is separated from a wafer makes it possible to make the protective film 24 formed on the side surfaces of the color filters 22 thinner than the protective film 24 formed on the top surface of the color filters 22. It is to be noted that the protective film 24 may be formed with use of, for example, a CVD method or an ALD method. The CVD method has superior coverage, and has a tendency that a vapor deposition material is isotropically deposited. In particular, the tendency is pronounced in the ALD method in which stacking is performed at an atomic level. Appropriately selecting these film formation methods makes it possible to control the film thickness of the protective film 24 formed on the top surfaces and the side surfaces of the color filters 22. Thus, the imaging device 1 illustrated in FIG. 1 is completed.

### Workings and Effects

In the imaging device 1 according to the present embodiment, the plurality of color filters 22 is provided one for each of the plurality of unit pixels P, the gap section X is provided between the respective color filters 22, and the light-blocking section 23 is formed at the bottom of the gap section X. This causes incident light to be reflected at an interface between the color filters 22 and the gap section X, which reduces absorption in the light-blocking section. This is described below.

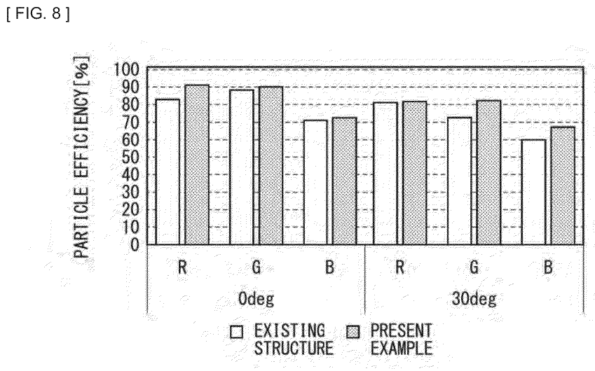

FIG. 6 is a light intensity distribution diagram in an optical simulation of a typical imaging device as a comparative example by an FDTD method. FIG. 7 is a light intensity distribution diagram in an optical simulation of the imaging device 1 according to the present embodiment by the FDTD method. FIG. 8 is a characteristic diagram illustrating results of quantum efficiencies at respective wavelengths (R, G, and B) by optical simulations of the respective imaging devices illustrated in FIG. 1 and FIG. 6 by the FDTD method.

In the typical imaging device, an on-chip lens (OCL) 1027 is provided on a color filter 1022, and light incident from above is condensed to a light-receiving section 1010 with use of the OCL 1027. However, as illustrated in FIG. 6, a fine pixel has an issue that a lens function of the OCL 1027 deteriorates and sensitivity loss is caused by a light-blocking section disposed between pixels.

In contrast, in the present embodiment, the gap section X is provided between the color filters 22 without providing an OCL, which causes the color filters 22 to have the lens function, and causes the light-blocking section 23 to be provided at the bottom of the gap section X. Thus, as illustrated in FIG. 7, light having entered the color filters from a subject without passing through the on-chip lens is reflected by a light phase shift caused by a refractive index difference between the color filters 22 and the gap section X without being absorbed by the light-blocking section 23, and is condensed to the photoelectric converter 12. Specifically, as illustrated in FIG. 8, the quantum efficiencies are improved at the respective wavelengths (R, G, and B), and a favorable result is obtained also in oblique incidence characteristic, as compared with the typical imaging device.

As described above, in the imaging device 1 according to the present embodiment, it is possible to reduce occurrence of color mixture while improving sensitivity.

In addition, in the imaging device 1 according to the present embodiment, the on-chip lens is not necessary, which makes it possible to achieve a lower profile. Achieving a lower profile makes it possible to also make the oblique incidence characteristics robust.

Further, in the typical imaging device, an interface between a color filter and an insulating film below the color filter is known as an interface having low adhesion. In a case where the plurality of color filters 22 is separately provided one for each of the unit pixels P as with the imaging device 1 according to the embodiment, there is a possibility that film peeling occurs at the interface between the insulating layer 21 and the color filters 22.

In contrast, in the present embodiment, for example, as illustrated in FIG. 4, the color filters 22 extend to the bottom of the light-blocking section 23, which makes it possible to reduce occurrence of film peeling at the interface between the insulating layer 21 and the color filters 22 by an anchor effect, and improve reliability.

Next, description is given of modification examples 1 to 13 of the present disclosure. Hereinafter, components similar to those in the embodiment described above are denoted by the same reference numerals, and description thereof is omitted as appropriate.

### 2. MODIFICATION EXAMPLES

### 2-1. Modification Example 1

In the embodiment described above, the imaging device 1 that detects a wavelength in the visible region has been described; however, for example, unit pixels P having sensitivity to an infrared ray may be mixed in the imaging device 1 for high-sensitivity imaging at a dark place and a sensing function using an LED light source. It is possible to provide such an imaging device by stacking a plurality of layers having transmission spectra different from each other as the color filters 22.

FIG. 9 schematically illustrates an example of a cross-sectional configuration of an imaging device (an imaging device 1A) according to the modification example 1 of the present disclosure. The imaging device 1A is, for example, a CMOS image sensor or the like used for an electronic apparatus such as a digital still camera or a video camera, and is, for example, what is called a back-illuminated imaging device, as with the embodiment described above.

In the unit pixel P (the red pixel Pr) that detects the red light (R), a color filter 21R and a color filter 21SIR are stacked. The color filter 21R allows the red light (R) to selectively pass therethrough. The color filter 21SIR allows visible light to pass therethrough and absorbs an infrared wavelength. In the unit pixel P (a green pixel Pg) that detects the green light (G), a color filter 21G and the color filter 21SIR are stacked. The color filter 21G allows the green light (G) to selectively pass therethrough. The color filter 21SIR allows visible light to pass therethrough and absorbs an infrared wavelength. In the unit pixel P (a blue pixel Pb) that detects the blue light (B), a color filter 21B and the color filter 21SIR are stacked. The color filter 21B allows the blue light (B) to selectively pass therethrough. The color filter 21SIR allows visible light to pass therethrough and absorbs an infrared wavelength. In the unit pixel P (an infrared pixel Pir) that detects an infrared ray (IR), for example, the color filter 21B and the color filter 21R are stacked. The color filter 21B allows the blue light (B) to selectively pass therethrough. The color filter 21R allows the red light (R) to selectively pass therethrough.

Thus, in the imaging device 1A, it is possible to detect wavelengths from a visible light region to an infrared region.

It is to be noted that in the present modification example, an example has been described in which the color filter 21B and the color filter 21R that complementarily absorb wavelengths in the visible light region are combined in the infrared pixel Pir, but the present modification example is not limited thereto. For example, any other color combination may be used, or a transparent filter may be used. On this occasion, in the infrared pixel Pir, wavelengths in the visible light region are also detected; however, it is possible to separate an output in the infrared region by signal processing.

### 2-2. Modification Example 2

FIG. 10 schematically illustrates an example of a cross-sectional configuration of an imaging device (an imaging device 1B) according to the modification example 2 of the present disclosure. The imaging device 1B is, for example, a CMOS image sensor or the like used for an electronic apparatus such as a digital still camera or a video camera, and is, for example, what is called a back-illuminated imaging device, as with the embodiment described above.

In the embodiment described above, the imaging device 1 including the color filters 22 having a substantially rectangular cross-sectional shape has been described, but the embodiment is not limited thereto. For example, as illustrated in FIG. 10, the color filters 22 that each have a top surface having a curved shape may be formed. It is possible to have the curved shape by controlling an exposure amount and a focus in a lithography process in processing the color filters 22.

Thus, in the present modification example, the top surfaces of the color filters 22 are curved surfaces; therefore, a geometrical lens effect is added to the color filters 22. This makes it possible to further reduce occurrence of color mixture while improving sensitivity, as compared with the embodiment described above.

It is to be noted that the curved shape of the top surface of the color filter 22 decreases a difference in effective refractive index between the color filter 22 and the gap section X. Accordingly, it is better in some cases not to have the curved shape.

### 2-3. Modification Example 3

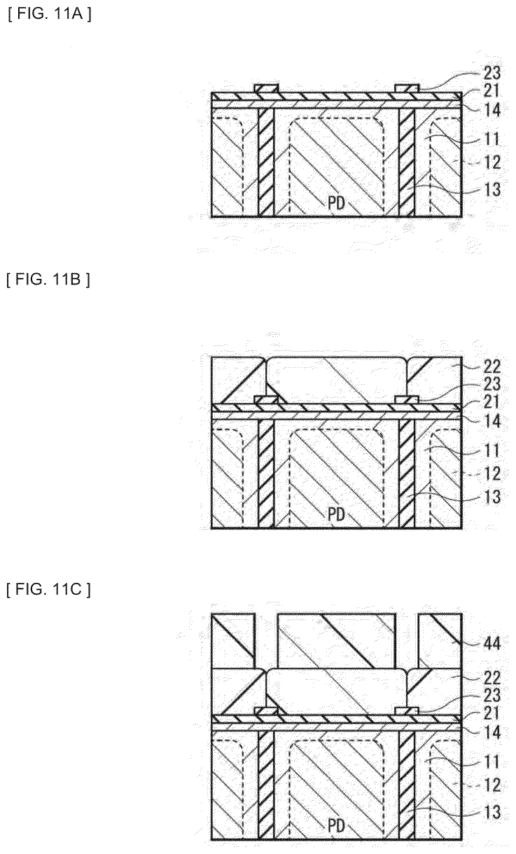

FIGS. 11A to 11C schematically illustrate another example of a method of manufacturing the imaging device 1 according to the embodiment described above. It is possible to form the imaging device 1 also as follows, for example.

As illustrated in FIG. 11A, the light-blocking section 23 is formed on the insulating layer 21, as with the embodiment described above. Subsequently, as illustrated in FIG. 11B, the color filters 22 are formed on the insulating layer 21 and the light-blocking section 23. Next, as illustrated in FIG. 11C, a resist 44 is patterned on the color filters 22. Thereafter, the gap section X is formed on the light-blocking section 23 with use of, for example, dry etching. Thereafter, the protective film 24 is formed, as with the embodiment described above. Thus, the imaging device 1 illustrated in FIG. 1 is completed.

In the manufacturing method according to the present modification example, as compared with a case where the manufacturing method according to the embodiment described above is used, it is possible to enhance rectangularity of the cross-sectional shape of each of the color filters 22. This makes it possible to enhance wave-optical light-condensing efficiency by a refractive index difference between the color filters 22 and the gap section X.

### 2-4. Modification Example 4

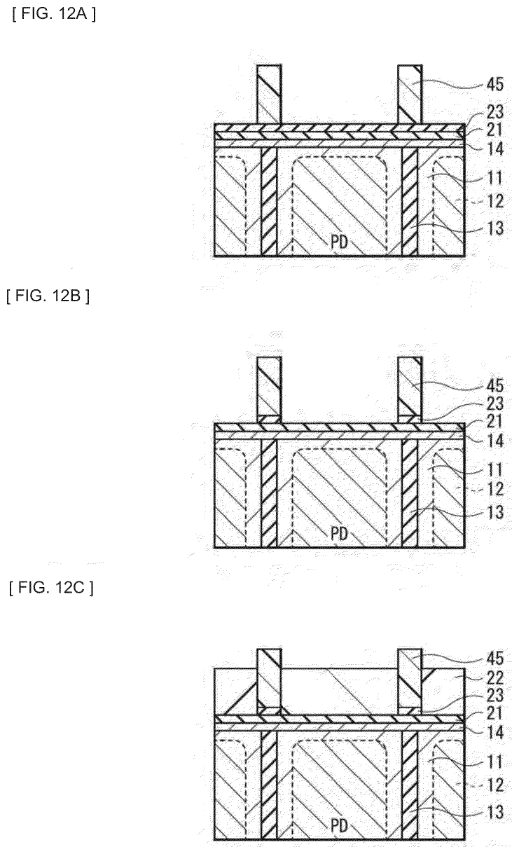

FIGS. 12A to 12C schematically illustrate another example of the method of manufacturing the imaging device 1 according to the embodiment described above. It is possible to form the imaging device 1 also as follows, for example.

As with the embodiment described above, after the light-blocking section 23 is formed on the insulating layer 21, a resist 45 is patterned on the light-blocking section 23, as illustrated in FIG. 12A. Subsequently, as illustrated in FIG. 12B, the light-blocking section 23 is etched with use of the resist 45 as a mask. Thereafter, as illustrated in FIG. 12C, the color filters 22 are formed with use of lithography technology. It is to be noted that the color filters 22 may be formed with use of spin-coating, exposure, development, post-baking, and the like, as with the embodiment described above. Thereafter, the resist 45 and a processing residue are removed by ashing or chemical processing. Alternatively, only the resist 45 may be removed, and the processing residue in processing the light-blocking section 23 may remain on the side surfaces of the color filters 22. This makes it possible to suppress occurrence of crosstalk.

It is to be noted that in a case where the processing residue adhered on a side surface of the resist 45 is formed higher than uppermost parts of the color filter 22, the resist 45 may be removed after CMP processing or the like is performed for planarization. This makes it possible to prevent the processing residue from remaining on the color filters 22, and suppress a decrease in sensitivity due to vignetting, and shading.

Thereafter, the protective film 24 is formed, as with the embodiment described above. Thus, the imaging device 1 illustrated in FIG. 1 is completed.

In the manufacturing method according to the present modification example, it is possible to form the gap section X by a self-alignment system.

### 2-5. Modification Example 5

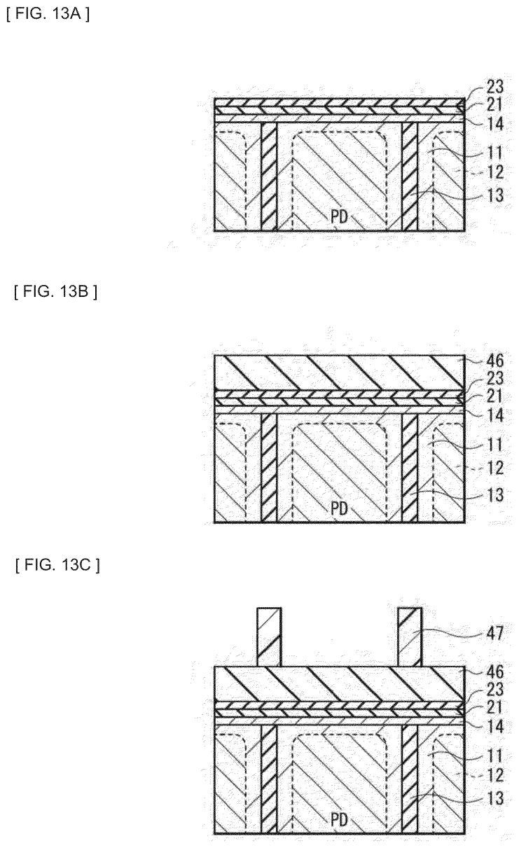

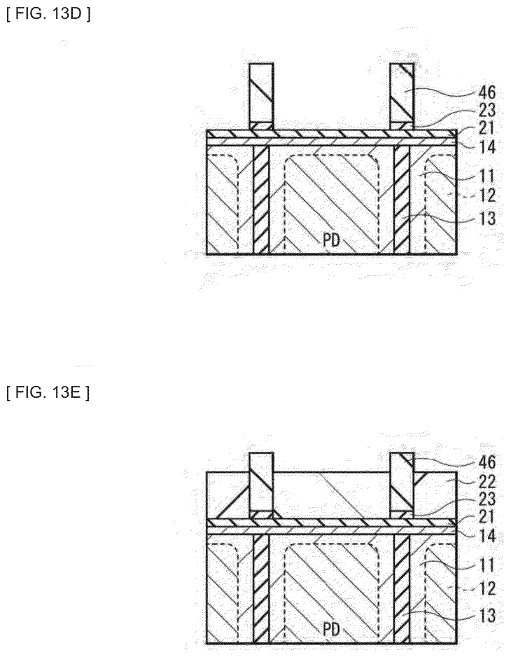

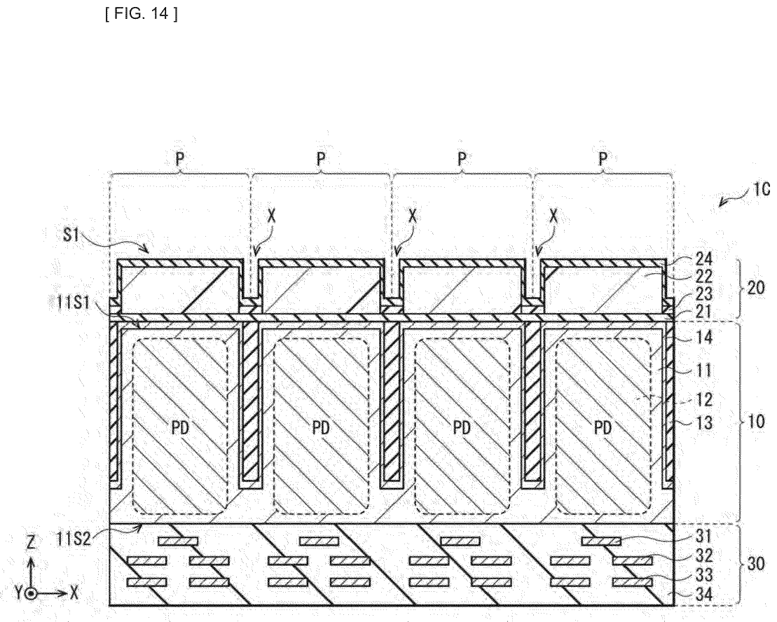

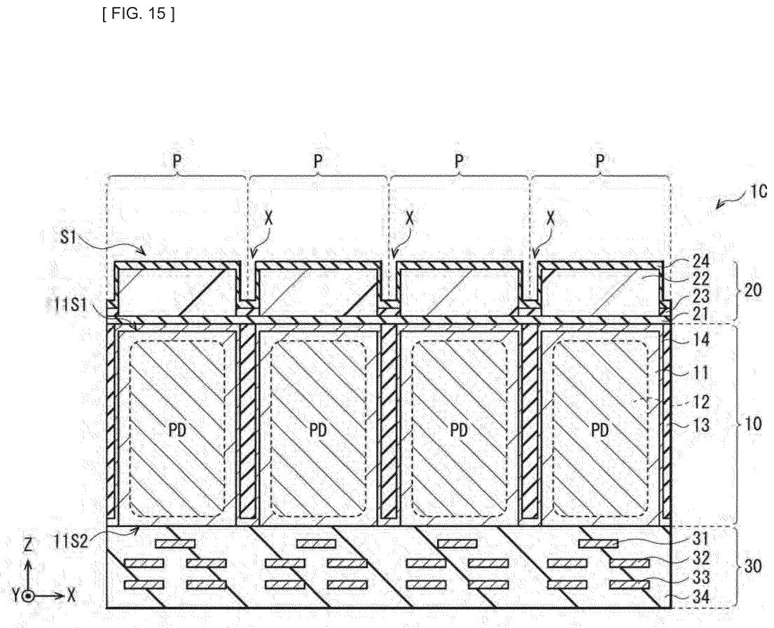

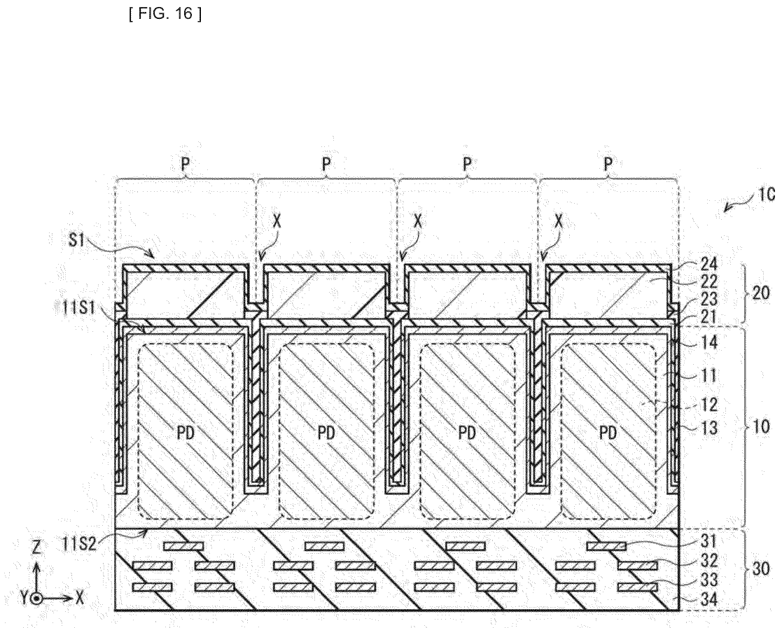

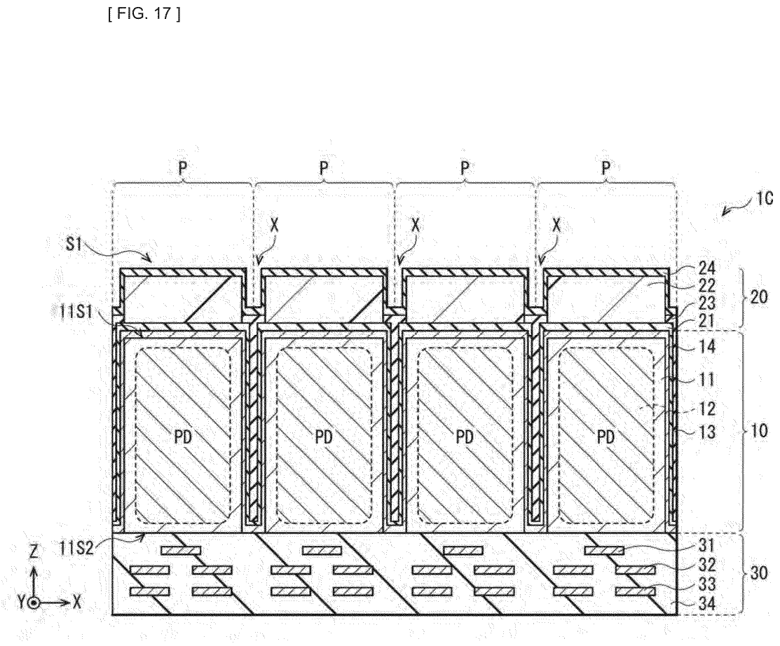

FIGS. 13A to 13E schematically illustrate another example of the method of manufacturing the imaging device 1 according to the embodiment described above. It is possible to form the imaging device 1 also as follows, for example.

As illustrated in FIG. 13A, the light-blocking section 23 is formed on the insulating layer 21, as with the embodiment described above. Subsequently, as illustrated in FIG. 13B, a sacrificial layer 46 is formed on the light-blocking section 23, for example, at 400° C. or less. The sacrificial layer 46 is formed with use of a material that has selective removability from the color filters 22 and the light-blocking section 23 and does not cause cross contamination. Examples of such a material include amorphous silicon and the like.

Subsequently, as illustrated in FIG. 13C, a resist 47 corresponding to a position where the gap section X is to be formed is patterned on the sacrificial layer 46. Next, as illustrated in FIG. 13D, the sacrificial layer 46 is patterned, and the light-blocking section 23 is etched with use of the sacrificial layer 46 as a hard mask. Subsequently, as illustrated in FIG. 13E, the color filters 22 are formed with use of lithography technology, as with the modification example 4 described above. It is to be noted that the color filters 22 may be formed with use of spin-coating, exposure, development, post-baking, and the like, as with the embodiment described above.

Thereafter, the sacrificial layer 46 is removed. For example, in a case where the sacrificial layer 46 is formed with use of amorphous silicon, it is possible to selectively remote the sacrificial layer 46 by an alkaline solution such as NH₄OH or KOH. At this time, as with the modification example 4 described above, in a case where a processing residue adhered on a side surface of the sacrificial layer 46 is formed higher than the uppermost parts of the color filters 22, the sacrificial layer 46 may be removed after CMP processing or the like is performed for planarization. This makes it possible to prevent the processing residue from remaining on the color filters 22, and suppress a decrease in sensitivity due to vignetting, and shading.

Thereafter, the protective film 24 is formed as with the embodiment described above. Thus, the imaging device 1 illustrated in FIG. 1 is completed.

In the manufacturing method described in the modification example 4 described above, mixing may occur depending on a combination of the materials of the color filters 22 and the resist 45. In addition, forming the gap section X thinly causes an increase in an aspect ratio; however, the resist has low stiffness, which may cause a possibility of pattern collapse during processing. In the present modification example, using the sacrificial layer 46 makes it possible to eliminate the possibility of pattern collapse.

### 2-6. Modification Example 6

FIG. 14 schematically illustrates an example of a cross-sectional configuration of an imaging device (an imaging device 1C) according to the modification example 6 of the present disclosure. FIG. 15 schematically illustrates another example of the cross-sectional configuration of the imaging device (the imaging device 1C) according to the modification example 6 of the present disclosure. The imaging device 1C is, for example, a CMOS image sensor or the like used for an electronic apparatus such as a digital still camera or a video camera, and is, for example, what is called a back-illuminated imaging device, as with the embodiment described above.

In the embodiment described above, an example has been described in which the element isolator 13 is formed by diffusing, for example, a p-type impurity, but the embodiment is not limited thereto. The element isolator 13 may have, for example, a STI (Shallow Trench Isolation, FIG. 14) structure or a FTI (Full Trench Isolation, FIG. 15) structure in which an opening is formed in the semiconductor substrate 11 from side of the first surface 11S1, and is filled with the insulating layer 21 after a side surface and a bottom surface of the opening are covered with the fixed electric charge layer 14. In addition, an air gap may be formed in the STI structure and the FTI structure.

Thus, in the imaging device 1C according to the present modification example, the element isolator 13 has the STI structure or the FTI structure; therefore, as compared with the imaging device 1 according to the embodiment described above, it is possible to suppress crosstalk between the unit pixels P adjacent to each other in the semiconductor substrate 11, and return stray light to an own pixel. Accordingly, it is possible to further improve sensitivity.

In addition, in the element isolator 13, the light-blocking section 23 may extend, as illustrated in FIGS. 16 and 17. This makes it possible to prevent crosstalk between the first surface 11S1 of the semiconductor substrate 11 and the light-blocking section 23.

### 2-7. Modification Example 7

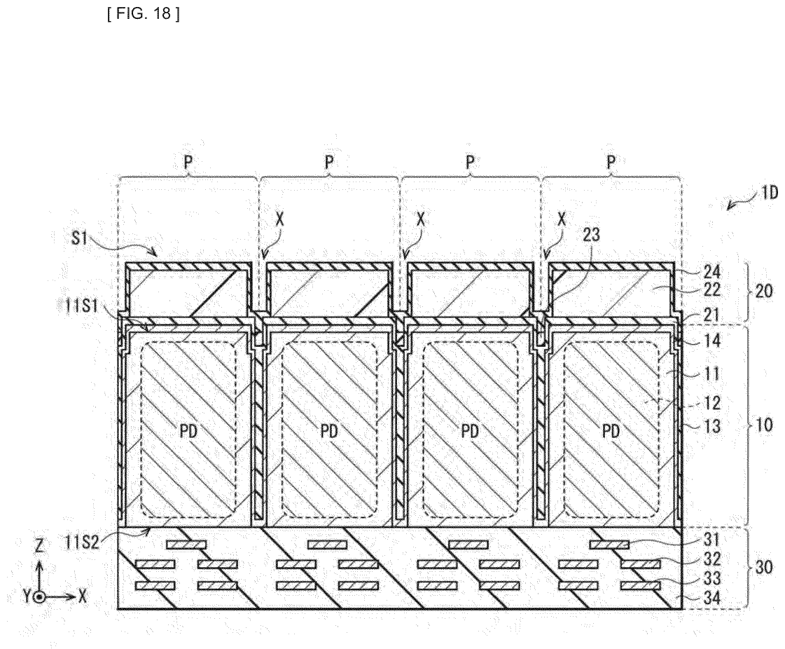

FIG. 18 schematically illustrates an example of a cross-sectional configuration of an imaging device (an imaging device 1D) according to the modification example 7 of the present disclosure. The imaging device 1D is, for example, a CMOS image sensor or the like used for an electronic apparatus such as a digital still camera or a video camera, and is, for example, what is called a back-illuminated imaging device, as with the embodiment described above.

In the embodiment described above, an example has been described in which a bottom surface of the light-blocking section 23 is provided on the insulating layer 21 so as to be substantially flush with bottom surfaces of the color filters 22, but the embodiment is not limited thereto. For example, as illustrated in FIG. 18, the light-blocking section 23 may be provided on side of the semiconductor substrate 11 rather than the bottom surfaces of the color filter 22. Specifically, the light-blocking section 23 may be embedded in the semiconductor substrate 11, and a trench may be filled with the light-blocking section 23 so as to cause the top surface thereof to be substantially flush with the first surface 11S1 of the semiconductor substrate 11. A width (B) of a trench not filled with the light-blocking section 23 may be narrower than a width (A) of a trench filled with the light-blocking section 23 (A>B). The width (A) of the trench and the width (B) of the trench preferably satisfy, for example, A/2>B.

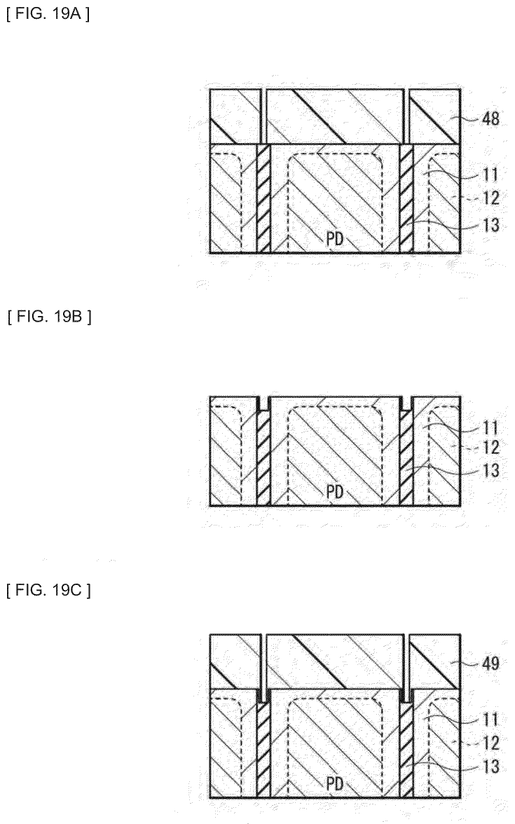

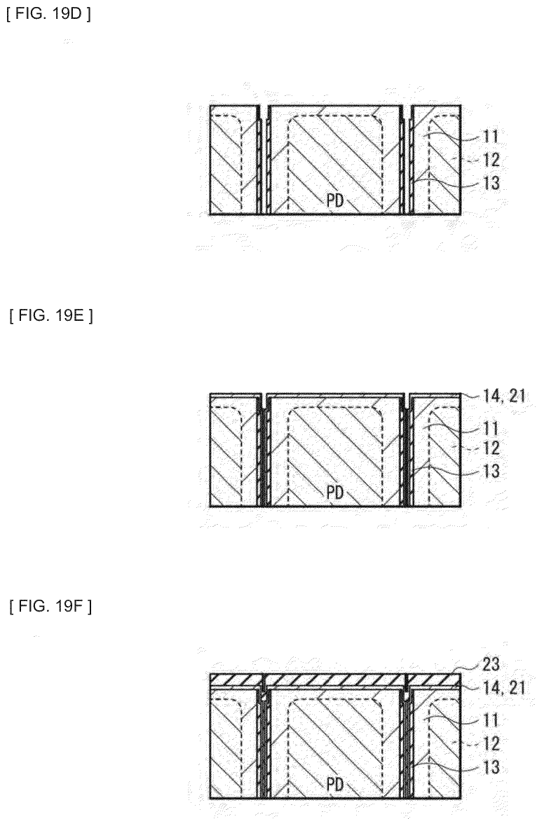

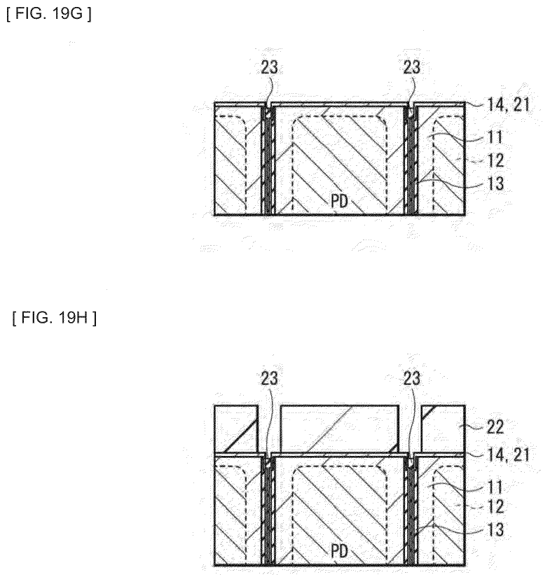

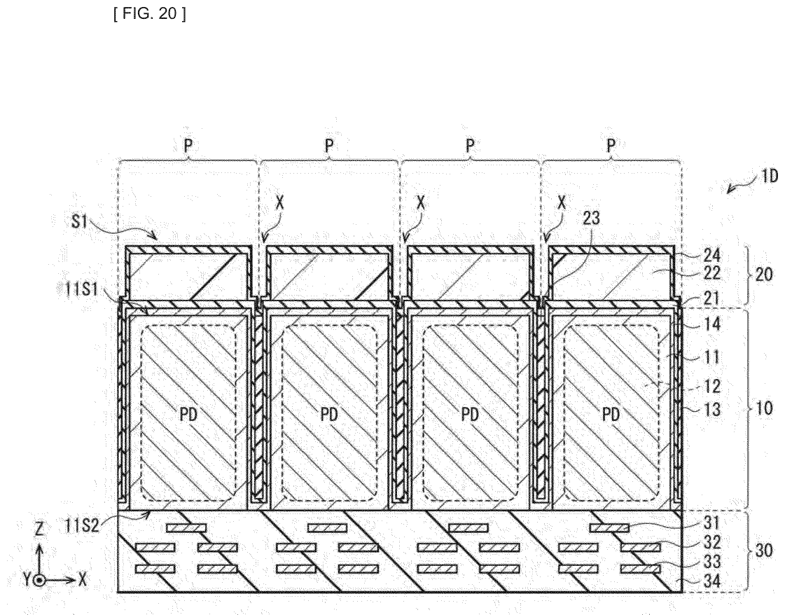

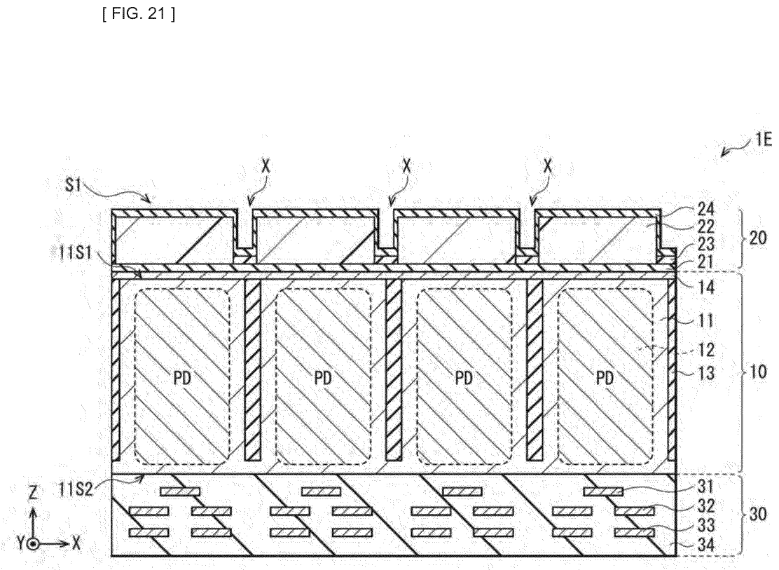

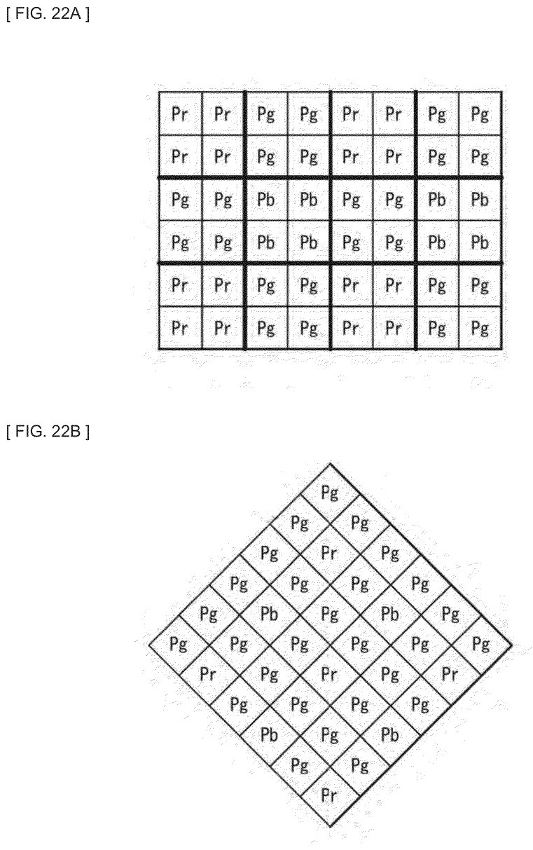

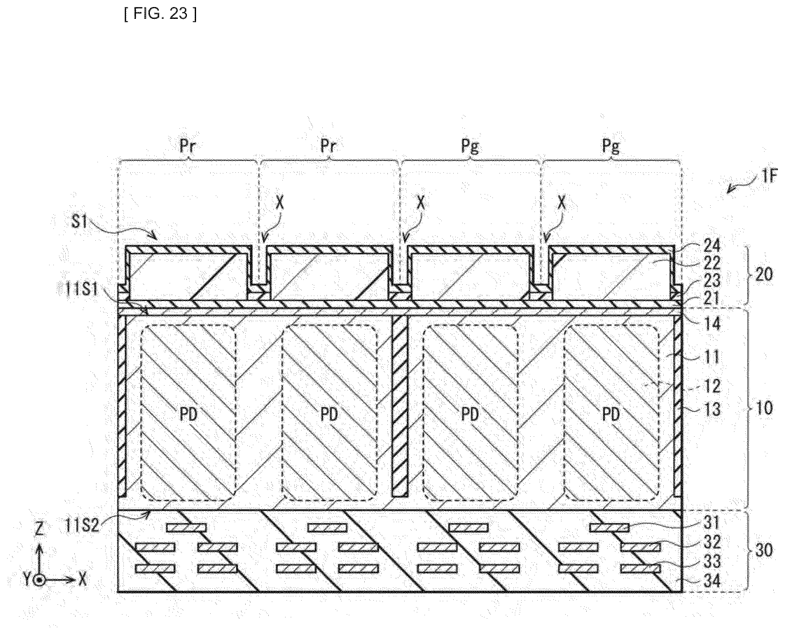

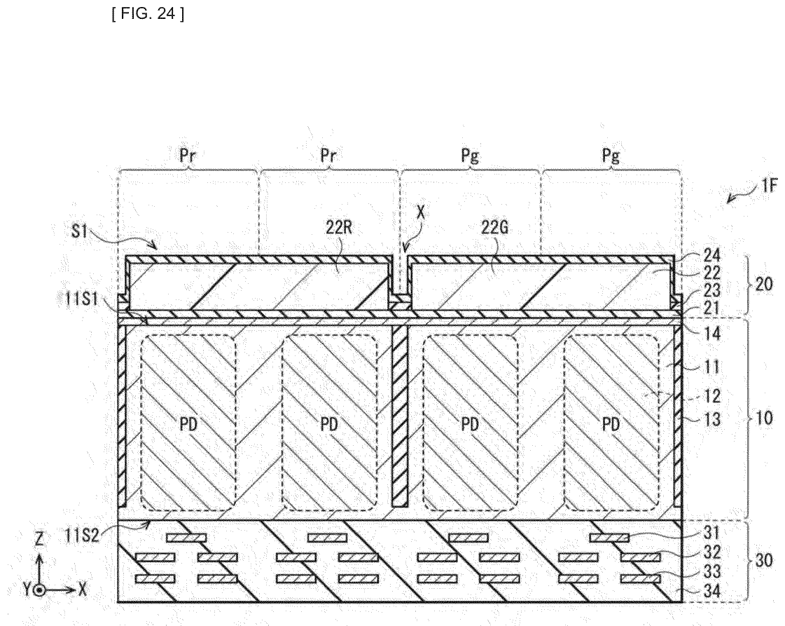

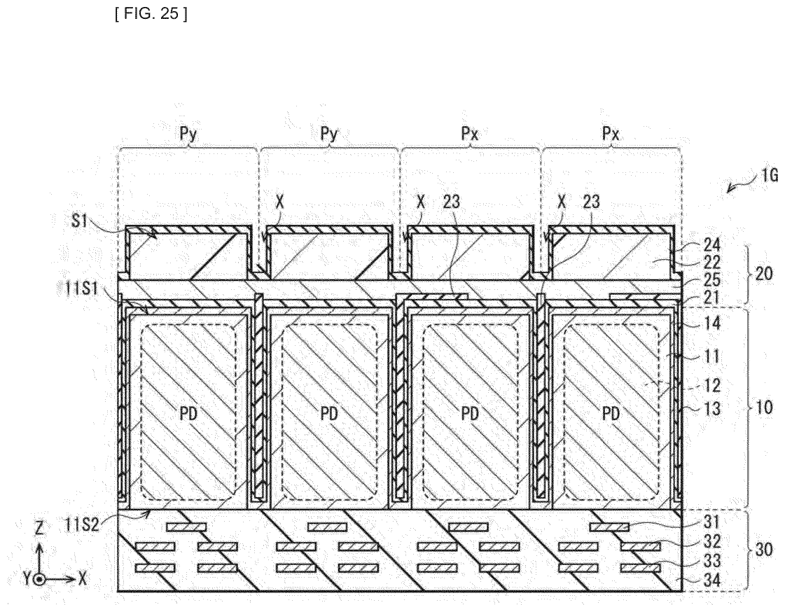

FIGS. 19A to 19H schematically illustrate a method of manufacturing the imaging device 1D.

First, as with the embodiment described above, the semiconductor substrate 11 is polished from side of the first surface 11S1 of the semiconductor substrate 11 to be thinned. Thereafter, as illustrated in FIG. 19A, a resist 48 having an opening on the element isolator 13 is patterned on the first surface 11S1 of the semiconductor substrate 11. Subsequently, as illustrated in FIG. 19B, a shallow trench is formed in the element isolator 13 with use of, for example, dry etching. Thereafter, the resist 48 is removed.

Next, as illustrated in FIG. 19C, a resist 49 having an opening narrower than the trench that has been formed earlier is patterned on the first surface 11S1 of the semiconductor substrate 11 with use of lithography technology. Substantially, for example, a trench that penetrates through the semiconductor substrate 11 is formed with use of, for example, dry etching. Thereafter, the resist 49 is removed, as illustrated in FIG. 19D. Processing in such a manner makes it possible to form a trench having a dual damascene structure.

Next, as illustrated in FIG. 19E, the fixed electric charge layer 14 and the insulating layer 21 are formed with use of, for example, an ALD method, a CVD method, or sputtering so as to block the trench with a terrace section of the dual damascene structure.

It is to be noted that the trench may be blocked by patterning the resist 48 as illustrated in FIG. 19A and then intentionally placing more weight on disposition in a Bosch process to perform taper processing. In the Bosch process, etching and deposition are alternately repeated. This makes it possible to block the trench at a midpoint in the trench.

Subsequently, as illustrated in FIG. 19F, the light-blocking section 23 is selectively formed on, for example, a planarized section including the terrace section of the dual damascene structure with use of, for example, long-throw sputtering. Next, as illustrated in FIG. 19G, the light-blocking section 23 on the semiconductor substrate 11 is polished by, for example, CMP, and is processed so as to leave only the light-blocking section 23 placed in the trench. Thereafter, as illustrated in FIG. 19H, as with the embodiment described above or the like, after the color filters 22 are formed, the protective film 24 is formed. Thus, the imaging device 1D illustrated in FIG. 18 is completed.

It is to be noted that in a case where the manufacturing method described above is used, the insulating layer 21 is preferably formed thickly in advance so as to prevent damage from being formed on the first surface 11S1 of the semiconductor substrate 11 due to over-polishing. For example, after the terrace section is blocked by an ALD method or the like, the insulating layer 21 may be formed again by long-throw sputtering.

Thus, in the imaging device 1D according to the present modification example, the light-blocking section 23 is embedded in the semiconductor substrate 11 so as to cause the top surface thereof to be substantially flush with the first surface 11S1 of the semiconductor substrate 11. This makes it possible to prevent crosstalk between the first surface 11S1 of the semiconductor substrate 11 and the light-blocking section 23 between the adjacent unit pixels P.

In addition, in the present modification example, the width of the trench not filled with the light-blocking section 23 is narrowed, which makes it possible to increase an area of the photoelectric converter 12 accordingly. This makes it possible to increase full-well electron capacity of the photoelectric converter 12 and improve sensitivity.

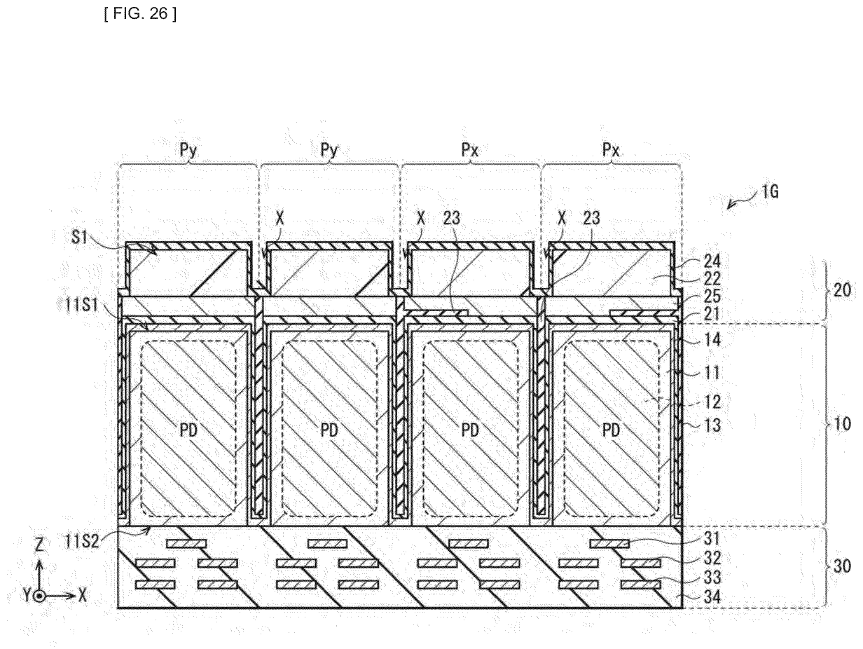

It is to be noted that in a case where the top surface of the light-blocking section 23 is positioned at least at a height less than or equal to 1/2 of the height of the color filter 22, it is possible to sufficiently reduce a decrease in sensitivity caused by absorption of incident light in the light-blocking section 23. Thus, in the imaging device 1D illustrated in FIG. 18, the light-blocking section 23 may be partially projected from the first surface 11S1 of the semiconductor substrate 11 to the light incident side. In addition, for example, the light-blocking section 23 may extend to a vicinity of the second surface 11S2 of the semiconductor substrate 11, as illustrated in FIG. 20.

### 2-8. Modification Example 8

FIG. 21 schematically illustrates an example of a cross-sectional configuration of an imaging device (an imaging device 1E) according to the modification example 8 of the present disclosure. The imaging device 1E is, for example, a CMOS image sensor or the like used for an electronic apparatus such as a digital still camera or a video camera, and is, for example, what is called a back-illuminated imaging device, as with the embodiment described above.

The imaging device (e.g., the imaging device 1) described in the embodiment described above or the like has a lower profile because the on-chip lens is not provided; therefore, pupil correction is basically unnecessary. However, for example, in a case where a module lens where light enters at an extreme angle is used for the imaging device, application of pupil correction makes it possible to bring out characteristics.

The imaging device 1E illustrated in FIG. 21 corresponds to the imaging device 1 according to the embodiment described above to which pupil correction is applied. Upon applying pupil correction, it is preferable that a pupil correction amount (a shift amount) of the gap section X be substantially the same as a pupil correction amount (a shift amount) of the light-blocking section 23, as illustrated in FIG. 21. However, a distance between the bottom surface of the color filter 22 and the light-blocking section 23 in a Z-axis direction is, for example, larger than or equal to 100 nm, it is preferable that the shift amount of the light-blocking section 23 be smaller than the shift amount of the color filter 22.

### 2-9. Modification Example 9

FIG. 22A schematically illustrates an example of a pixel arrangement in an imaging device (an imaging device 1F) according to the modification example 9 of the present disclosure. FIG. 22B schematically illustrates another example of the pixel arrangement in the imaging device (the imaging device 1F) according to the modification example 9 of the present disclosure. FIGS. 23 and 24 each schematically illustrate an example of a cross-sectional configuration of the imaging device 1F having a pixel arrangement in which unit pixels P of the same color are disposed adjacent to each other in the pixel section 100A, as illustrated in FIGS. 22A and 22B. The imaging device 1F is, for example, a CMOS image sensor or the like used for an electronic apparatus such as a digital still camera or a video camera, and is, for example, what is called a back-illuminated imaging device, as with the embodiment described above.

The pixel arrangement illustrated in FIG. 22A is called a Quad arrangement, in which the unit pixels P of the same color (e.g., the red pixels Pr, the green pixels Pg, and the blue pixels Pb) are disposed in a matrix with two rows and two columns as one set. The pixel arrangement illustrated in FIG. 22B is called a clear bit arrangement, in which pixels are obliquely disposed to increase resolution, and a plurality of green pixels Pg is disposed adjacent to each other.

In a case where the unit pixels P of the same color are provided adjacent to each other in such a manner, for example, as illustrated in FIG. 23, the element isolator 13 between the unit pixels P of the same color adjacent to each other (e.g., between the red pixels Pr adjacent to each other and between the green pixels Pg adjacent to each other) may be omitted. In addition, as illustrated in FIG. 24, the light-blocking section 23 between the unit pixels P of the same color adjacent to each other (e.g., between the red pixels Pr adjacent to each other and between the green pixels Pg adjacent to each other) may be omitted, and the color filters 22 (e.g., the color filters 22R or 22G) may be continuously formed. Alternatively, a configuration in which structures in FIGS. 23 and 24 are combined may be adopted.

Thus, it is possible to improve sensitivity because one or both of the element isolator 13 and the light-blocking section 23 are not provided.

### 2-10. Modification Example 10

FIG. 25 schematically illustrates an example of a cross-sectional configuration of an imaging device (an imaging device 1G) according to the modification example 10 of the present disclosure. FIG. 26 schematically illustrates another example of the cross-sectional configuration of the imaging device 1G according to the modification example 10 of the present disclosure. The imaging device 1G is, for example, a CMOS image sensor or the like used for an electronic apparatus such as a digital still camera or a video camera, and is, for example, what is called a back-illuminated imaging device, as with the embodiment described above.

The imaging device 1G according to the present modification example includes the unit pixel P (an image-plane phase-difference pixel Py) that is able to obtain parallax information together with the unit pixel P (an imaging pixel Px) that obtains imaging information. The image-plane phase-difference pixel Py divides a pupil region of an imaging lens, and photoelectrically converts a subject image from a divided pupil region to generate a signal for phase difference detection.

In the present modification example, description is given of a configuration of an imaging device including the image-plane phase-difference pixel Py pupil-divided with use of a light-blocking metal.

In the imaging device 1G, as with the imaging device 1C illustrated in FIG. 17 for example, the light-blocking section 23 may be embedded in the semiconductor substrate 11. In the imaging device 1G, the light-blocking section 23 also serves a light-blocking metal that performs pupil division, and is formed extending on, for example, the insulating layer 21. In the imaging device 1G, adjusting a light-condensing point to an image-plane phase-difference light-blocking metal makes it possible to improve separability of each pupil-divided image and improve distance measurement accuracy. In order to adjust the light-condensing point to the light-blocking metal, it is desired to separately provide the color filters 22 having a lens function and the light-blocking metal. Accordingly, an insulating layer 25 is provided between the insulating layer 21 and the color filters 22.

For example, as illustrated in FIG. 26, a light-blocking wall that penetrates through the insulating layer 25 may be provided in the light-blocking section 23. This makes it possible to suppress occurrence of crosstalk between the first surface 11S1 of the semiconductor substrate 11 and the color filters 22 caused by providing the insulating layer 25.

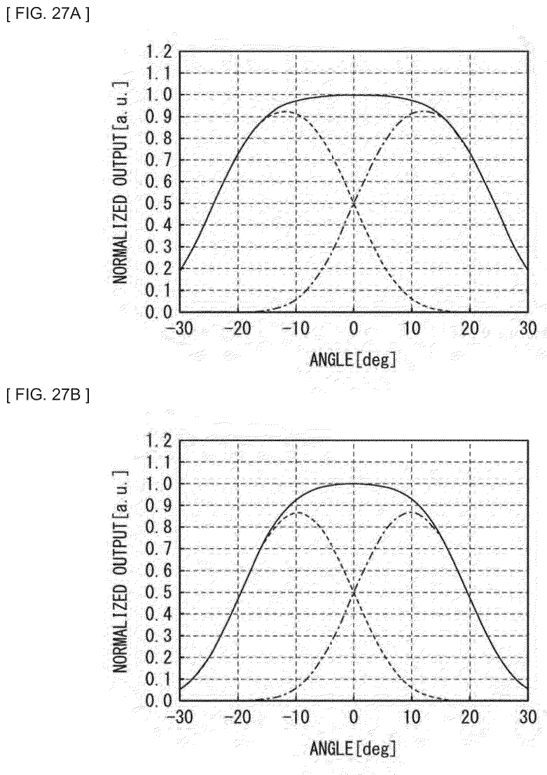

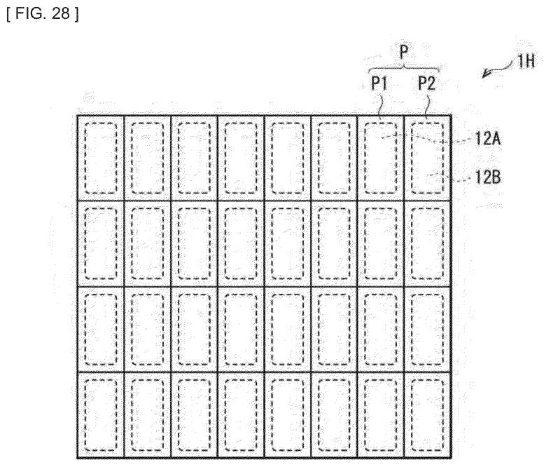

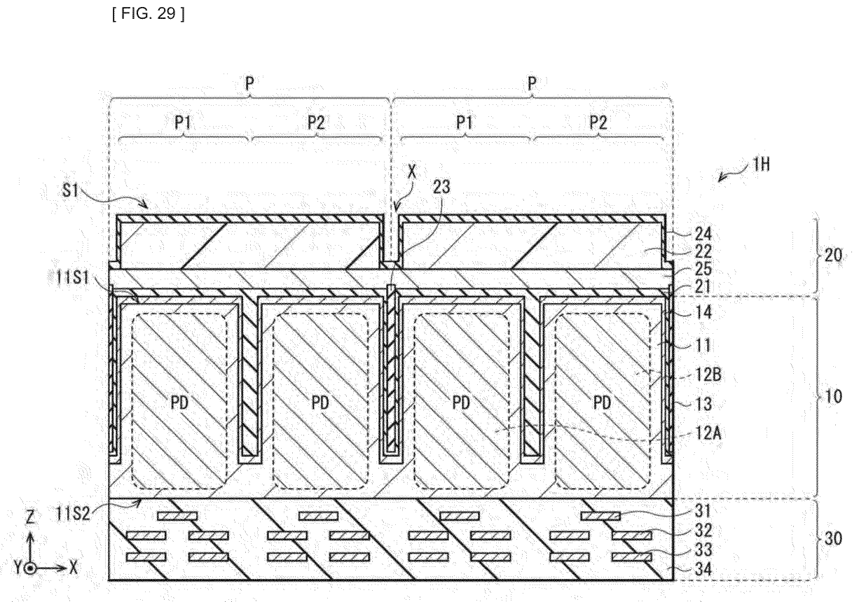

FIGS. 27A and 27B respectively illustrate oblique incidence characteristics of the imaging devices 1G illustrated in FIGS. 25 and 26. As with the imaging device 1G illustrated in FIG. 26, in a case where the light-blocking section 23 is provided so as to penetrate through the insulating layer 25, oblique incidence characteristics on high angle side deteriorates as illustrated in FIG. 27B; however, in a case where a module lens does not use that region, sensitivity to unnecessary light is suppressed. Accordingly, it is possible to reduce occurrence of flare.

### 2-11. Modification Example 11

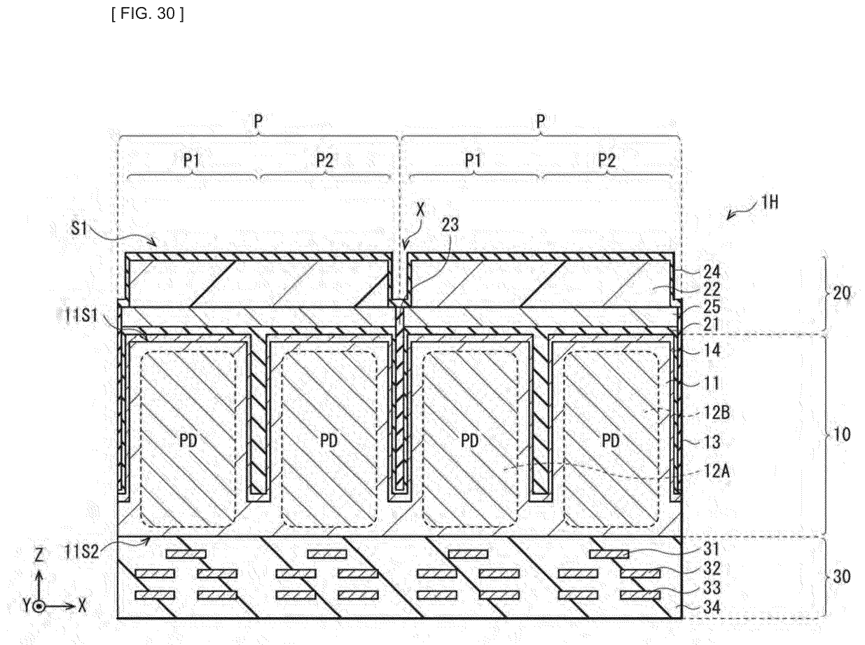

FIG. 28 schematically illustrates an example of a pixel arrangement in an imaging device (an imaging device 1H) according to the modification example 11 of the present disclosure. FIG. 29 schematically illustrates an example of a cross-sectional configuration of the imaging device 1H illustrated in FIG. 28. FIG. 30 schematically illustrates another example of the cross-sectional configuration of the imaging device 1H illustrated in FIG. 28. The imaging device 1H is, for example, a CMOS image sensor or the like used for an electronic apparatus such as a digital still camera or a video camera, and is, for example, what is called a back-illuminated imaging device, as with the embodiment described above.

In the imaging device 1H according to the present modification example, the plurality of unit pixels P is each configured to be able to simultaneously obtain imaging information and parallax information. In other words, the plurality of unit pixels P each serves as an imaging pixel and an image-plane phase-difference pixel. The imaging pixel photoelectrically converts, in the photodiode PD, a subject image formed by an imaging lens to generate a signal for image generation. The image-plane phase-difference pixel divides a pupil region of an imaging lens, and photoelectrically converts a subject image from a divided pupil region to generate a signal for phase difference detection.

In the present modification example, description is given of an imaging device using a pupil division technique by dividing the photoelectric converter 12 (PD).

In the imaging device 1H, a plurality of photoelectric converters (e.g., two photoelectric converters 12A and 12B) is formed so as to be embedded in each unit pixel P. The unit pixel P includes a sub-pixel P1 including the photoelectric converter 12A and a sub-pixel P2 including the photoelectric converter 12B. In the unit pixel P, for example, a signal electric charge generated in the photoelectric converter 12A and a signal electric charge generated in the photoelectric converter 12B are each read out. In the unit pixel P, the signal electric charges read from the respective photoelectric converters 12A and 12B are outputted to, for example, a phase-difference operation block of an external signal processor, and a distance between a subject and an image by the photoelectric converter 12A is calculated from a shift amount of an image by the photoelectric converter 12B, which make it possible to obtain a lens driving amount necessary for autofocusing. In addition, the signal electric charges generated in the respective photoelectric converters 12A and 12B are added together in the floating diffusion FD, and are outputted to, for example, an imaging block of an external signal processor, which make is possible to obtain a pixel signal based on the all the electric charges of the photoelectric converter 12A and the photoelectric converter 12B. Alternatively, respective pieces of information about the signal electric charges of the photoelectric converters 12A and 12B separately read for phase difference calculation may be added in subsequent signal processing.

In the imaging device 1H, as illustrated in FIG. 29, the color filter 22 is shared by the sub-pixel P1 and the sub-pixel P2. In addition, as with the modification example 10 described above, the insulating layer 25 is provided between the insulating layer 21 and the color filters 22. Furthermore, for example, as illustrated in FIG. 29, the light-blocking section 23 is formed so that the top surface of the light-blocking section 23 is projected toward the light incident side S1 from the first surface 11S1 of the semiconductor substrate 11. Alternatively, for example, as illustrated in FIG. 30, the light-blocking section 23 may be formed extending on the light incident side S1 so as to penetrate through the insulating layer 25. This makes it possible to suppress occurrence of crosstalk between the first surface 11S1 of the semiconductor substrate 11 and the color filters 22 caused by providing the insulating layer 25.

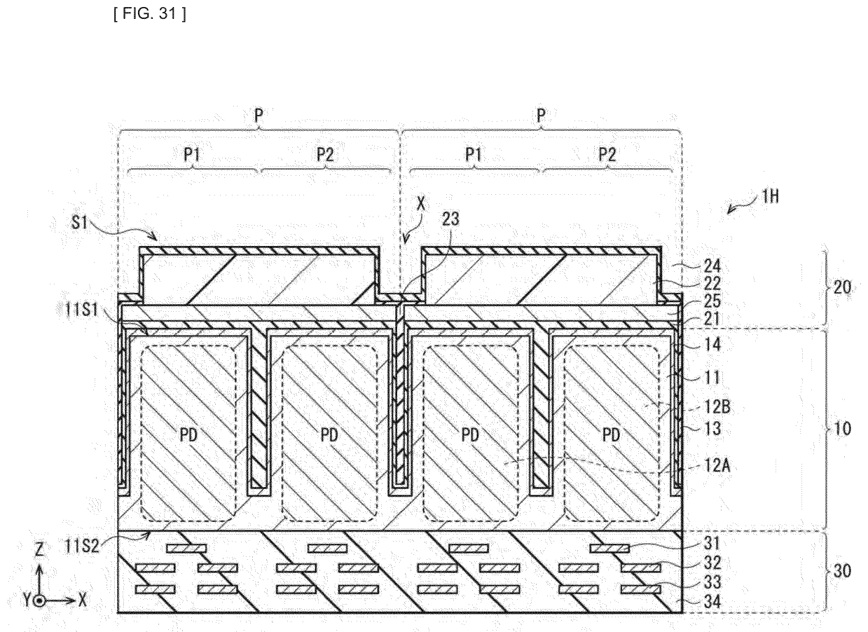

Furthermore, in the imaging device 1H, it is possible to achieve an optimum focusing state for an image-plane phase difference by the shapes of the color filters 22. For example, as illustrated in FIG. 31, increasing the width of the gap section X makes it possible to weaken light-condensing power and increase a focal length. On this occasion, the light-blocking section 23 is extended on the light incident side S1 so as to penetrate through the insulating layer 25, and is further extended in a planar direction in accordance with the width of the gap section X, which makes it possible to reduce an increase in crosstalk. Alternatively, the present modification example may be combined with the modification example 2 to cause the top surface of the color filter 22 to have a curved shape, thus controlling the light-condensing point.

### 2-12. Modification Example 12

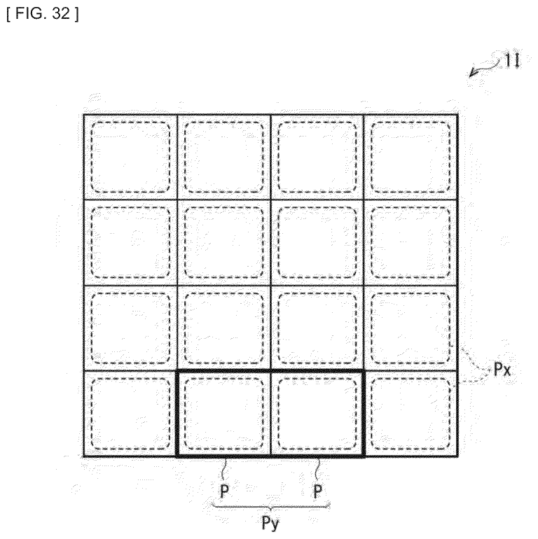

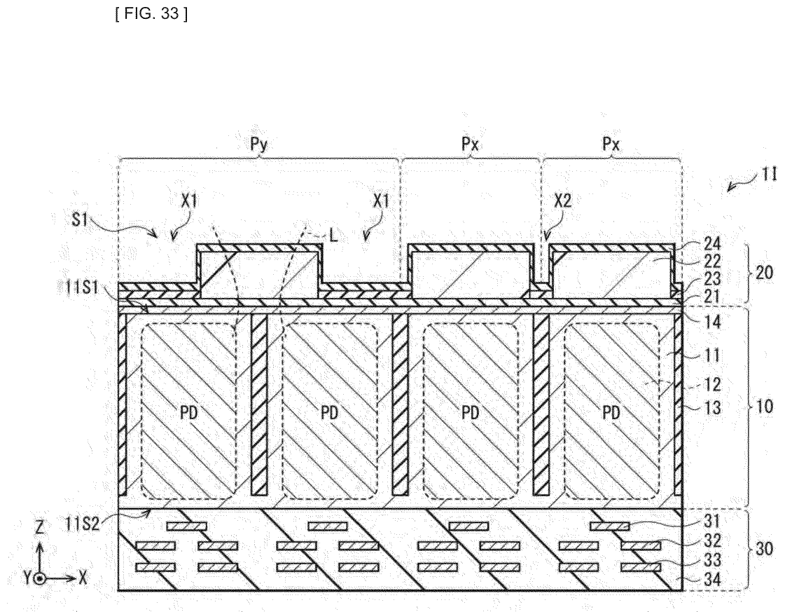

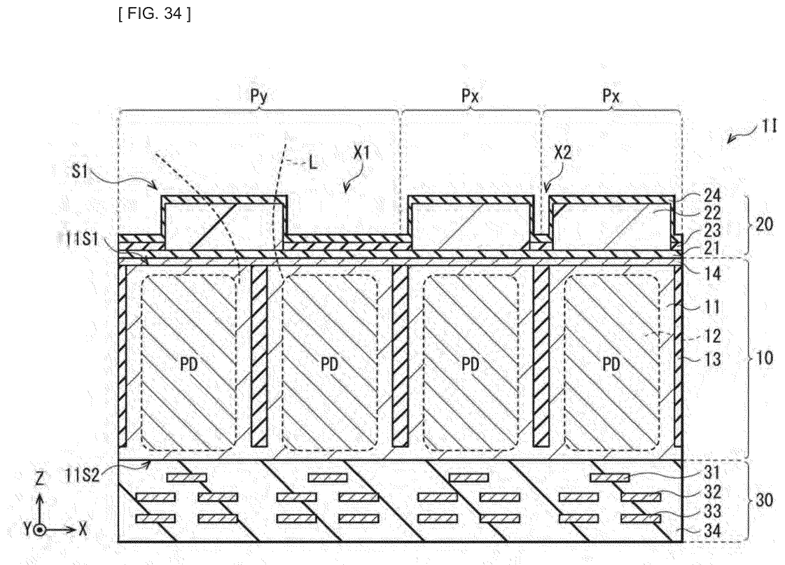

FIG. 32 schematically illustrates an example of a pixel arrangement in an imaging device (an imaging device 1I) according to the modification example 12 of the present disclosure. FIG. 33 schematically illustrates an example of a cross-sectional configuration of the imaging device 1I illustrated in FIG. 32. The imaging device 1I is, for example, a CMOS image sensor or the like used for an electronic apparatus such as a digital still camera or a video camera, and is, for example, what is called a back-illuminated imaging device, as with the embodiment described above.

The imaging device 1I according to the present modification example includes the unit pixel P (the image-plane phase-difference pixel Py) that is able to obtain parallax information together with the unit pixel P (the imaging pixel Px) that obtains imaging information. The image-plane phase-difference pixel Py divides a pupil region of an imaging lens, and photoelectrically converts a subject image from a divided pupil region to generate a signal for phase difference detection. In the present modification example, description is given of a configuration of an imaging device including, for example, the image-plane phase-difference pixel Py that includes two adjacent unit pixels P.

In the image-plane phase-difference pixel Py, the color filter 22 is provided over the two unit pixels P included in the image-plane phase-difference pixel Py. In addition, a gap section X1 in a longitudinal direction of the image-plane phase-difference pixel Py (a direction where the two unit pixels P included in the image-plane phase-difference pixel Py are provided side by side) (in other words, the gap section X1 provided between the image-plane phase-difference pixel Px and the imaging pixel Px) is provided wider than that of a gap section X2 between the adjacent imaging pixels Px. Accordingly, light to enter the image-plane phase-difference pixel Py is condensed to a boundary between the adjacent unit pixels P, which makes it possible to improve separation performance. Further, it is preferable that the light-blocking section 23 be formed in accordance with the width of the gap section X. This makes it possible to suppress occurrence of crosstalk to the image-plane phase-difference pixel Py.

In addition, for example, as illustrated in FIG. 34, the position of the color filter 22 provided in the image-plane phase-difference pixel Py may be shifted for each image height in accordance with a light incident angle from a module lens. In other words, the color filter 22 provided in the image-plane phase-difference pixel Py may be provided at a position shifted toward an optical center of the pixel section 100A in accordance with the position in the pixel section 100A. Shift amounts of the color filters 22 differ substantially concentrically from the optical center of the pixel section 100A.

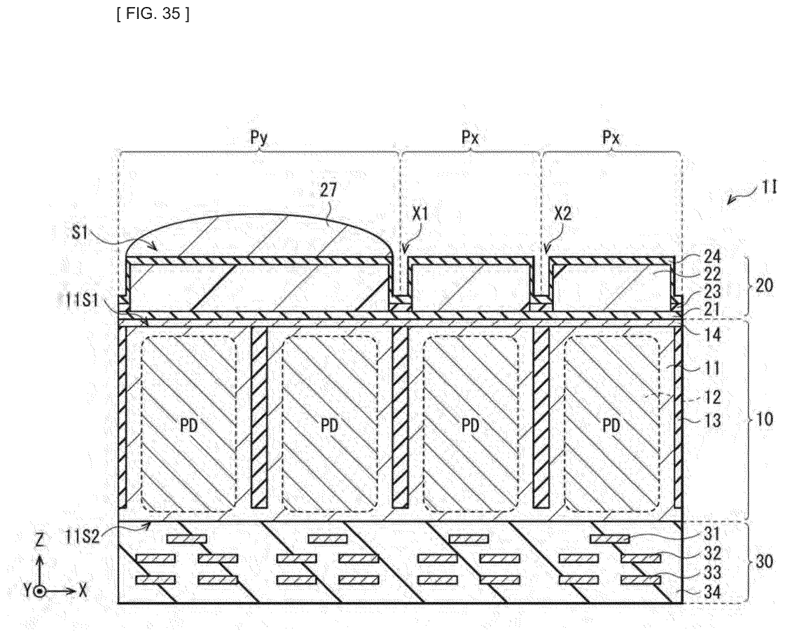

Further, in the image-plane phase-difference pixel Py, for example, as illustrated in FIG. 35, an OCL 27 may be provided. This makes it possible to increase light-condensing power of a lens and improve separation performance in the image-plane phase-difference pixel Py.

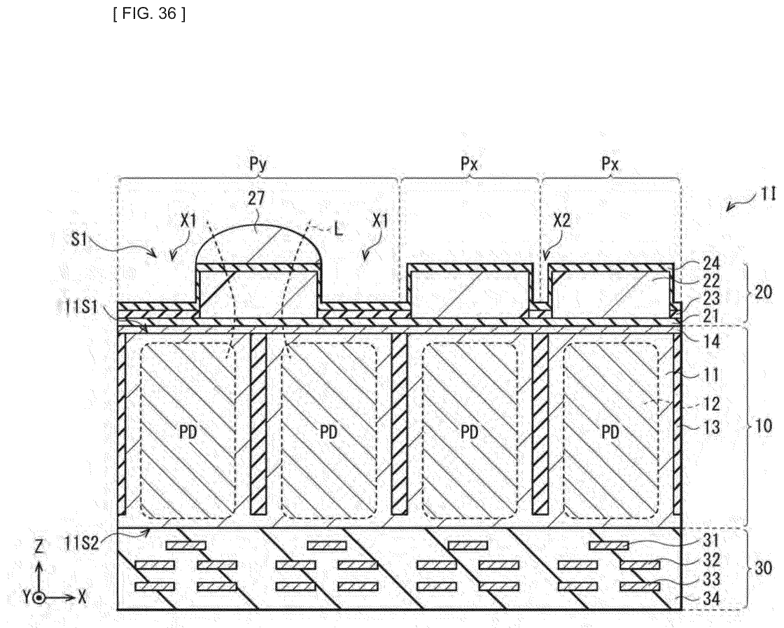

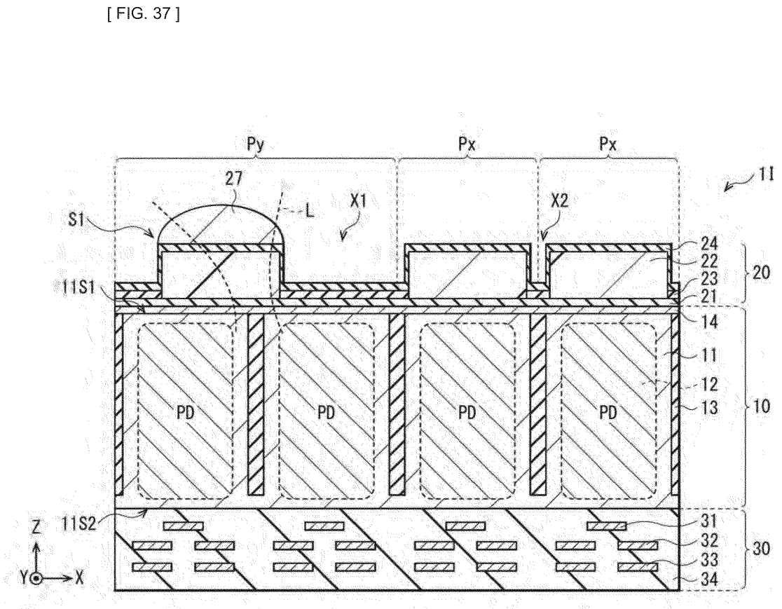

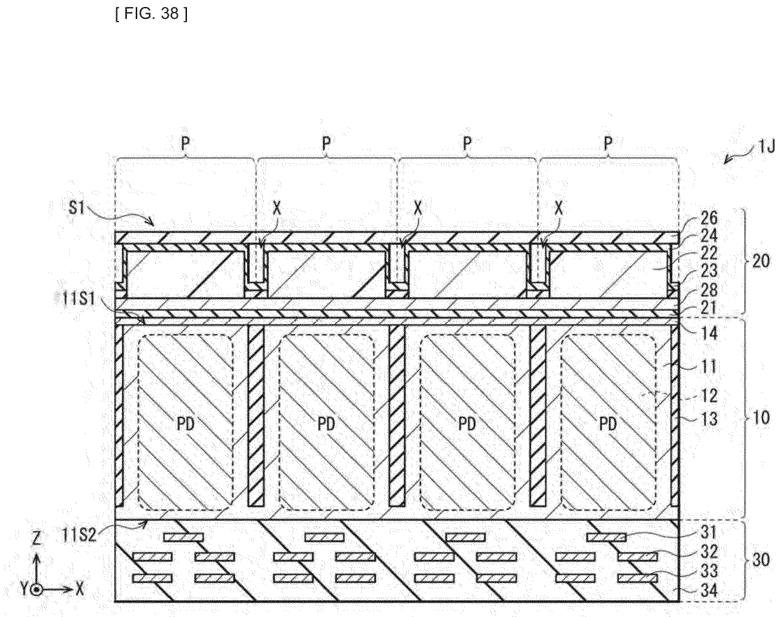

It is to be noted that, for example, as illustrated in FIG. 36, the OCL 27 may be provided on the color filter 22 that causes the gap section X1 in the longitudinal direction of the image-plane phase-difference pixel Py (a direction where two unit pixels P are provided side by side) to be wider than the gap section X2 between the adjacent imaging pixels Px. In addition, for example, as illustrated in FIG. 37, the OCL 27 may be provided on the color filter 22 of which the position is shifted for each image height in accordance with the light incident angle from the module lens.

### 2-13. Modification Example 13

FIG. 38 schematically illustrates an example of a cross-sectional configuration of an imaging device (an imaging device 1J) according to the modification example 13 of the present disclosure. The imaging device 1J is, for example, a CMOS image sensor or the like used for an electronic apparatus such as a digital still camera or a video camera, and is, for example, what is called a back-illuminated imaging device, as with the embodiment described above.

The imaging device 1J according to the present modification example includes a protective film 26 and the gap section X. The protective film 26 is continuously provided over a plurality of color filters 22 above the plurality of color filters 22. The gap section X is provided between the adjacent color filters 22. The protective film 26 is formed with use of, for example, a technique without coatability. This makes it possible to block an upper end of the gap section X without filling the gap section X. Examples of the technique without coatability include sputtering. In addition, after a sacrificial layer is formed in a region corresponding to the gap section X, the color filters 22 are formed, and the protective film 26 is formed on the color filters 22 and the sacrificial layer. Thereafter, the sacrificial layer is removed by a chemical solution or dry etching. This makes it possible to form the gap section X having the upper end blocked by the protective film 26. It is to be noted that it is possible for the chemical solution and the dry etching to enter from an outermost circumferential side surface region of the pixel section 100A. However, an extremely small opening may be formed in the protective film 26 in a pixel boundary section in a lithography process and a dry etching process to secure a chemical solution entry route to the sacrificial layer. As one example, in a case where the sacrificial layer is formed with use of Cu, a method of removing the sacrificial layer is, for example, wet etching using a mixed liquid of a phosphoric acid, a sulfuric acid, or a hydrochloric acid, and a hydrogen peroxide solution. In a case where the sacrificial layer is formed with use of Al or Ti, the method of removing the sacrificial layer is, for example, dry etching using a chlorine gas. This makes it possible to reduce periodicity by the color filters 22 and the gap section X and reduce occurrence of flare.

In addition, in the embodiment described above, as illustrated in FIG. 4, an example has been described in which the color filter 22 extends to the bottom of the light-blocking section 23 to enhance adhesion between the insulating layer 21 and the color filter 22, but the embodiment is not limited thereto. For example, as illustrated in FIG. 38, providing an adhesion layer 28 between the insulating layer 21 and both the color filters 22 and the light-blocking section 23 also makes it possible to prevent film peeling between the insulating layer 21 and the color filters 22. It is possible to form the adhesion layer 28 with use of, for example, an organic material having adjusted viscosity and light transmissivity. Examples of such an organic material include an acrylic and epoxy resins and the like.

It is to be noted that it is possible to use the adhesion layer 28, for example, as a lift-off layer by a failure in patterning in a subsequent process or a wet chemical solution in peeling and regeneration for device trouble. In addition, in a case where there is a possibility that the adhesion layer 28 is altered due to contact with a metal layer, a transparent inorganic film may be formed below the adhesion layer 28 for protection.

### 3. APPLICATION EXAMPLES

### Application Example 1

The imaging device 1 or the like described above is applicable to various kinds of electronic apparatuses having imaging functions. Examples of the electronic apparatuses include camera systems such as digital still cameras and video cameras and mobile phones having the imaging functions. FIG. 39 illustrates a schematic configuration of an electronic apparatus 1000.

The electronic apparatus 1000 includes, for example, a lens group 1001, the imaging device 1, a DSP (Digital Signal Processor) circuit 1002, a frame memory 1003, a display section 1004, a storage section 1005, an operation section 1006, and a power supply section 1007, which are coupled to each other through a bus line 1008.

The lens group 1001 captures incident light (image light) from a subject to form an image on an imaging plane of the imaging device 1. The imaging device 1 converts the light amount of the incident light of which the image is formed on the imaging plane by the lens group 1001 into an electric signal on a pixel-by-pixel basis, and supplies the electrical signal as a pixel signal to the DSP circuit 1002.

The DSP circuit 1002 is a signal processing circuit that processes a signal supplied from the imaging device 1. The DSP circuit 1002 outputs image data obtained by processing the signal from the imaging device 1. The frame memory 1003 temporarily holds the image data processed by the DSP circuit 1002 on a frame-by-frame basis.

The display section 1004 includes, for example, a panel-type display device such as a liquid crystal panel or an organic EL (Electro Luminescence) panel, and records image data of a moving image or a still image captured by the imaging device 1, on a recording medium such as a semiconductor memory or a hard disk.

In accordance with an operation by a user, the operation section 1006 outputs an operation signal concerning various functions of the electronic apparatus 1000. The power supply section 1007 supplies the DSP circuit 1002, the frame memory 1003, the display section 1004, the storage section 1005, and the operation section 1006 with various types of power as power for operating these supply targets as appropriate.

### Application Example 2

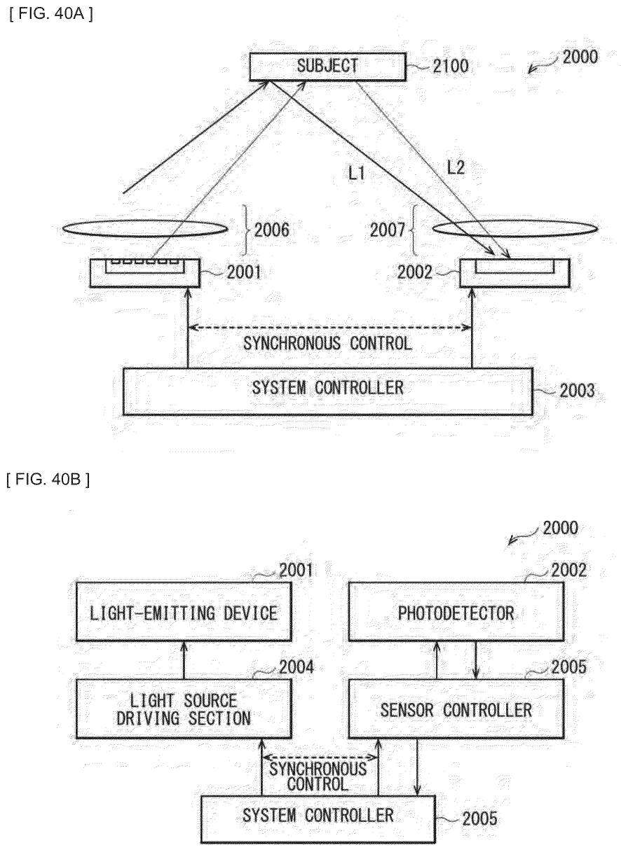

FIG. 40A schematically illustrates an example of an entire configuration of a photodetection system 2000 including the imaging device 1. FIG. 40B illustrates an example of a circuit configuration of the photodetection system 2000. The photodetection system 2000 includes a light-emitting device 2001 as a light source section that emits infrared light L2, and a photodetector 2002 as a light-receiving section including a photoelectric conversion element. As the photodetector 2002, it is possible to use the imaging device 1 described above. The photodetection system 2000 may further include a system controller 2003, a light source driving section 2004, a sensor controller 2005, a light source-side optical system 2006, and a camera-side optical system 2007.

The photodetector 2002 is able to detect light L1 and light L2. The light L1 is ambient light from outside reflected by a subject (a measurement object) 2100 (FIG. 40A). The light L2 is light emitted from the light-emitting device 2001 and then reflected by the subject 2100. The light L1 is, for example, visible light, and the light L2 is, for example, infrared light. The light L1 is detectable by a photoelectric converter in the photodetector 2002, and the light L2 is detectable by a photoelectric conversion region in the photodetector 2002. It is possible to obtain image information of the subject 2100 from the light L1 and obtain distance information between the subject 2100 and the photodetection system 2000 from the light L2. It is possible to mount the photodetection system 2000 on, for example, an electronic apparatus such as a smartphone and a mobile body such as a car. It is possible to configure the light-emitting device 2001 with, for example, a semiconductor laser, a surface-emitting semiconductor laser, or a vertical cavity surface emitting laser (VCSEL). As a method of detecting the light L2 emitted from the light-emitting device 2001 by the photodetector 2002, for example, it is possible to adopt an iTOF method; however, the method is not limited thereto. In the iTOF method, the photoelectric converter is able to measure a distance to the subject 2100 by time of flight (Time-of-Flight; TOF), for example. As a method of detecting the light L2 emitted from the light-emitting device 2001 by the photodetector 2002, it is also possible to adopt, for example, a structured light method or a stereovision method. For example, in the structured light method, light having a predetermined pattern is projected on the subject 2100, and distortion of the pattern is analyzed, thereby making it possible to measure the distance between the photodetection system 2000 and the subject 2100. In addition, in the stereovision method, for example, two or more cameras are used to obtain two or more images of the subject 2100 viewed from two or more different viewpoints, thereby making it possible to measure the distance between the photodetection system 2000 and the subject. It is to be noted that it is possible to synchronously control the light-emitting device 2001 and the photodetector 2002 by the system controller 2003.

### Practical Application Examples

### (Practical Application Example to Endoscopic Surgery System)

The technology according to the present disclosure (present technology) is applicable to various products. For example, the technology according to the present disclosure may be applied to an endoscopic surgery system.

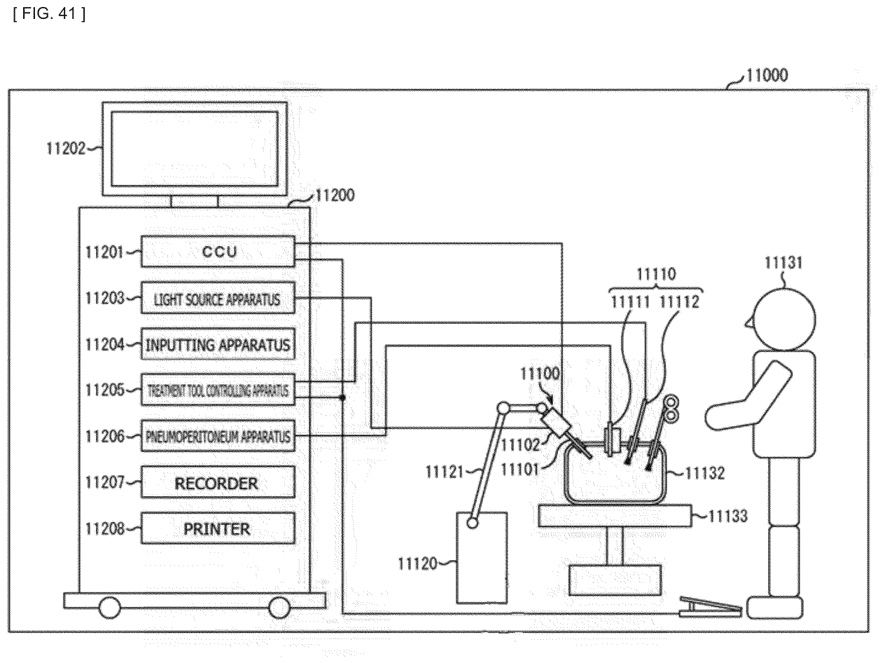

FIG. 41 is a view depicting an example of a schematic configuration of an endoscopic surgery system to which the technology according to an embodiment of the present disclosure (present technology) can be applied.

In FIG. 41, a state is illustrated in which a surgeon (medical doctor) 11131 is using an endoscopic surgery system 11000 to perform surgery for a patient 11132 on a patient bed 11133. As depicted, the endoscopic surgery system 11000 includes an endoscope 11100, other surgical tools 11110 such as a pneumoperitoneum tube 11111 and an energy device 11112, a supporting arm apparatus 11120 which supports the endoscope 11100 thereon, and a cart 11200 on which various apparatus for endoscopic surgery are mounted.

The endoscope 11100 includes a lens barrel 11101 having a region of a predetermined length from a distal end thereof to be inserted into a body cavity of the patient 11132, and a camera head 11102 connected to a proximal end of the lens barrel 11101. In the example depicted, the endoscope 11100 is depicted which includes as a rigid endoscope having the lens barrel 11101 of the hard type. However, the endoscope 11100 may otherwise be included as a flexible endoscope having the lens barrel 11101 of the flexible type.

The lens barrel 11101 has, at a distal end thereof, an opening in which an objective lens is fitted. A light source apparatus 11203 is connected to the endoscope 11100 such that light generated by the light source apparatus 11203 is introduced to a distal end of the lens barrel 11101 by a light guide extending in the inside of the lens barrel 11101 and is irradiated toward an observation target in a body cavity of the patient 11132 through the objective lens. It is to be noted that the endoscope 11100 may be a forward-viewing endoscope or may be an oblique-viewing endoscope or a side-viewing endoscope.

An optical system and an image pickup element are provided in the inside of the camera head 11102 such that reflected light (observation light) from the observation target is condensed on the image pickup element by the optical system. The observation light is photo-electrically converted by the image pickup element to generate an electric signal corresponding to the observation light, namely, an image signal corresponding to an observation image. The image signal is transmitted as RAW data to a CCU 11201.

The CCU 11201 includes a central processing unit (CPU), a graphics processing unit (GPU) or the like and integrally controls operation of the endoscope 11100 and a display apparatus 11202. Further, the CCU 11201 receives an image signal from the camera head 11102 and performs, for the image signal, various image processes for displaying an image based on the image signal such as, for example, a development process (demosaic process).

The display apparatus 11202 displays thereon an image based on an image signal, for which the image processes have been performed by the CCU 11201, under the control of the CCU 11201.

The light source apparatus 11203 includes a light source such as, for example, a light emitting diode (LED) and supplies irradiation light upon imaging of a surgical region to the endoscope 11100.

An inputting apparatus 11204 is an input interface for the endoscopic surgery system 11000. A user can perform inputting of various kinds of information or instruction inputting to the endoscopic surgery system 11000 through the inputting apparatus 11204. For example, the user would input an instruction or a like to change an image pickup condition (type of irradiation light, magnification, focal distance or the like) by the endoscope 11100.

A treatment tool controlling apparatus 11205 controls driving of the energy device 11112 for cautery or incision of a tissue, sealing of a blood vessel or the like. A pneumoperitoneum apparatus 11206 feeds gas into a body cavity of the patient 11132 through the pneumoperitoneum tube 11111 to inflate the body cavity in order to secure the field of view of the endoscope 11100 and secure the working space for the surgeon. A recorder 11207 is an apparatus capable of recording various kinds of information relating to surgery. A printer 11208 is an apparatus capable of printing various kinds of information relating to surgery in various forms such as a text, an image or a graph.

It is to be noted that the light source apparatus 11203 which supplies irradiation light when a surgical region is to be imaged to the endoscope 11100 may include a white light source which includes, for example, an LED, a laser light source or a combination of them. Where a white light source includes a combination of red, green, and blue (RGB) laser light sources, since the output intensity and the output timing can be controlled with a high degree of accuracy for each color (each wavelength), adjustment of the white balance of a picked up image can be performed by the light source apparatus 11203. Further, in this case, if laser beams from the respective RGB laser light sources are irradiated time-divisionally on an observation target and driving of the image pickup elements of the camera head 11102 are controlled in synchronism with the irradiation timings. Then images individually corresponding to the R, G and B colors can be also picked up time-divisionally. According to this method, a color image can be obtained even if color filters are not provided for the image pickup element.

Further, the light source apparatus 11203 may be controlled such that the intensity of light to be outputted is changed for each predetermined time. By controlling driving of the image pickup element of the camera head 11102 in synchronism with the timing of the change of the intensity of light to acquire images time-divisionally and synthesizing the images, an image of a high dynamic range free from underexposed blocked up shadows and overexposed highlights can be created.

Further, the light source apparatus 11203 may be configured to supply light of a predetermined wavelength band ready for special light observation. In special light observation, for example, by utilizing the wavelength dependency of absorption of light in a body tissue to irradiate light of a narrow band in comparison with irradiation light upon ordinary observation (namely, white light), narrow band observation (narrow band imaging) of imaging a predetermined tissue such as a blood vessel of a superficial portion of the mucous membrane or the like in a high contrast is performed. Alternatively, in special light observation, fluorescent observation for obtaining an image from fluorescent light generated by irradiation of excitation light may be performed. In fluorescent observation, it is possible to perform observation of fluorescent light from a body tissue by irradiating excitation light on the body tissue (autofluorescence observation) or to obtain a fluorescent light image by locally injecting a reagent such as indocyanine green (ICG) into a body tissue and irradiating excitation light corresponding to a fluorescent light wavelength of the reagent upon the body tissue. The light source apparatus 11203 can be configured to supply such narrow-band light and/or excitation light suitable for special light observation as described above.

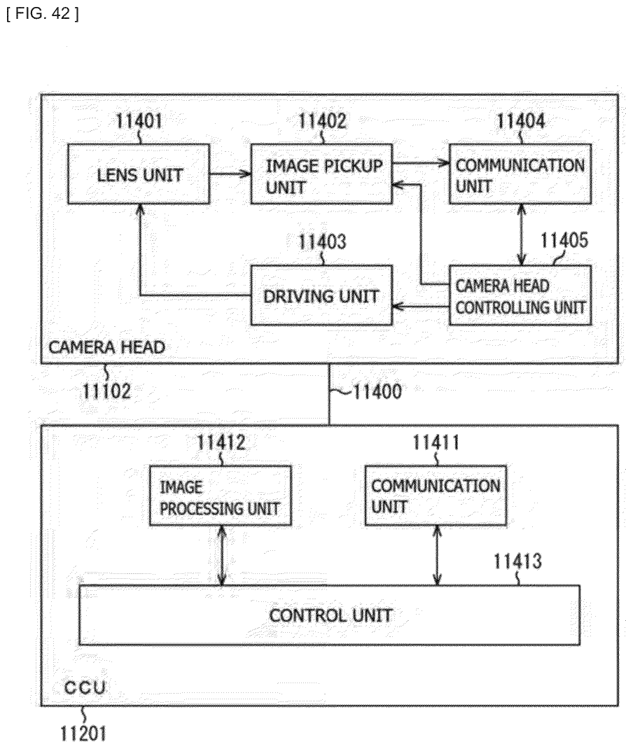

FIG. 42 is a block diagram depicting an example of a functional configuration of the camera head 11102 and the CCU 11201 depicted in FIG. 41.

The camera head 11102 includes a lens unit 11401, an image pickup unit 11402, a driving unit 11403, a communication unit 11404 and a camera head controlling unit 11405. The CCU 11201 includes a communication unit 11411, an image processing unit 11412 and a control unit 11413. The camera head 11102 and the CCU 11201 are connected for communication to each other by a transmission cable 11400.

The lens unit 11401 is an optical system, provided at a connecting location to the lens barrel 11101. Observation light taken in from a distal end of the lens barrel 11101 is guided to the camera head 11102 and introduced into the lens unit 11401. The lens unit 11401 includes a combination of a plurality of lenses including a zoom lens and a focusing lens.

The number of image pickup elements which is included by the image pickup unit 11402 may be one (single-plate type) or a plural number (multi-plate type). Where the image pickup unit 11402 is configured as that of the multi-plate type, for example, image signals corresponding to respective R, G and B are generated by the image pickup elements, and the image signals may be synthesized to obtain a color image. The image pickup unit 11402 may also be configured so as to have a pair of image pickup elements for acquiring respective image signals for the right eye and the left eye ready for three dimensional (3D) display. If 3D display is performed, then the depth of a living body tissue in a surgical region can be comprehended more accurately by the surgeon 11131. It is to be noted that, where the image pickup unit 11402 is configured as that of stereoscopic type, a plurality of systems of lens units 11401 are provided corresponding to the individual image pickup elements.

Further, the image pickup unit 11402 may not necessarily be provided on the camera head 11102. For example, the image pickup unit 11402 may be provided immediately behind the objective lens in the inside of the lens barrel 11101.

The driving unit 11403 includes an actuator and moves the zoom lens and the focusing lens of the lens unit 11401 by a predetermined distance along an optical axis under the control of the camera head controlling unit 11405. Consequently, the magnification and the focal point of a picked up image by the image pickup unit 11402 can be adjusted suitably.

The communication unit 11404 includes a communication apparatus for transmitting and receiving various kinds of information to and from the CCU 11201. The communication unit 11404 transmits an image signal acquired from the image pickup unit 11402 as RAW data to the CCU 11201 through the transmission cable 11400.

In addition, the communication unit 11404 receives a control signal for controlling driving of the camera head 11102 from the CCU 11201 and supplies the control signal to the camera head controlling unit 11405. The control signal includes information relating to image pickup conditions such as, for example, information that a frame rate of a picked up image is designated, information that an exposure value upon image picking up is designated and/or information that a magnification and a focal point of a picked up image are designated.

It is to be noted that the image pickup conditions such as the frame rate, exposure value, magnification or focal point may be designated by the user or may be set automatically by the control unit 11413 of the CCU 11201 on the basis of an acquired image signal. In the latter case, an auto exposure (AE) function, an auto focus (AF) function and an auto white balance (AWB) function are incorporated in the endoscope 11100.

The camera head controlling unit 11405 controls driving of the camera head 11102 on the basis of a control signal from the CCU 11201 received through the communication unit 11404.

The communication unit 11411 includes a communication apparatus for transmitting and receiving various kinds of information to and from the camera head 11102. The communication unit 11411 receives an image signal transmitted thereto from the camera head 11102 through the transmission cable 11400.

Further, the communication unit 11411 transmits a control signal for controlling driving of the camera head 11102 to the camera head 11102. The image signal and the control signal can be transmitted by electrical communication, optical communication or the like.

The image processing unit 11412 performs various image processes for an image signal in the form of RAW data transmitted thereto from the camera head 11102.

The control unit 11413 performs various kinds of control relating to image picking up of a surgical region or the like by the endoscope 11100 and display of a picked up image obtained by image picking up of the surgical region or the like. For example, the control unit 11413 creates a control signal for controlling driving of the camera head 11102.

Further, the control unit 11413 controls, on the basis of an image signal for which image processes have been performed by the image processing unit 11412, the display apparatus 11202 to display a picked up image in which the surgical region or the like is imaged. Thereupon, the control unit 11413 may recognize various objects in the picked up image using various image recognition technologies. For example, the control unit 11413 can recognize a surgical tool such as forceps, a particular living body region, bleeding, mist when the energy device 11112 is used and so forth by detecting the shape, color and so forth of edges of objects included in a picked up image. The control unit 11413 may cause, when it controls the display apparatus 11202 to display a picked up image, various kinds of surgery supporting information to be displayed in an overlapping manner with an image of the surgical region using a result of the recognition. Where surgery supporting information is displayed in an overlapping manner and presented to the surgeon 11131, the burden on the surgeon 11131 can be reduced and the surgeon 11131 can proceed with the surgery with certainty.

The transmission cable 11400 which connects the camera head 11102 and the CCU 11201 to each other is an electric signal cable ready for communication of an electric signal, an optical fiber ready for optical communication or a composite cable ready for both of electrical and optical communications.

Here, while, in the example depicted, communication is performed by wired communication using the transmission cable 11400, the communication between the camera head 11102 and the CCU 11201 may be performed by wireless communication.

One example of the endoscopic surgery system to which the technology according to the present disclosure may be applied has been described above. The technology according to the present disclosure may be applied to, for example, the image pickup unit 11402 among the configurations described above. Applying the technology according to the present disclosure to the image pickup unit 11402 makes it possible to improve detection accuracy.

It is to be noted that the endoscopic surgery system has been described here as an example, but the technology according to the present disclosure may be additionally applied to, for example, a microscopic surgery system and the like.

### (Practical Application Example to Mobile Body)

The technology according to the present disclosure is applicable to various products. For example, the technology according to the present disclosure may be achieved in the form of an apparatus to be mounted to a mobile body of any kind such as an automobile, an electric vehicle, a hybrid electric vehicle, a motorcycle, a bicycle, a personal mobility, an airplane, a drone, a vessel, a robot, a construction machine, and an agricultural machine (tractor).

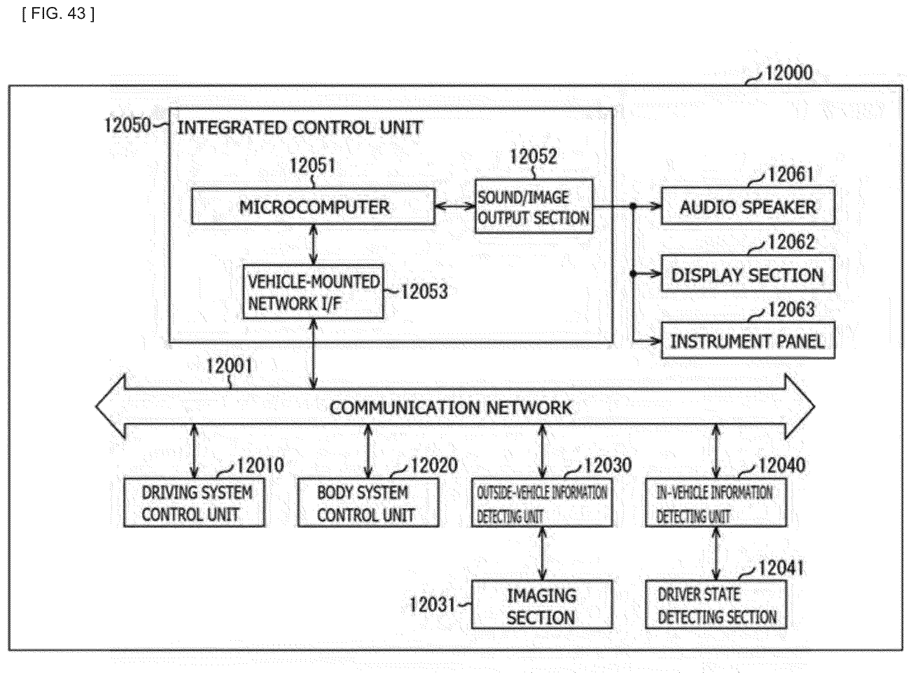

FIG. 43 is a block diagram depicting an example of schematic configuration of a vehicle control system as an example of a mobile body control system to which the technology according to an embodiment of the present disclosure can be applied.

The vehicle control system 12000 includes a plurality of electronic control units connected to each other via a communication network 12001. In the example depicted in FIG. 43, the vehicle control system 12000 includes a driving system control unit 12010, a body system control unit 12020, an outside-vehicle information detecting unit 12030, an in-vehicle information detecting unit 12040, and an integrated control unit 12050. In addition, a microcomputer 12051, a sound/image output section 12052, and a vehicle-mounted network interface (I/F) 12053 are illustrated as a functional configuration of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, the outside-vehicle information detecting unit 12030 is connected with an imaging section 12031. The outside-vehicle information detecting unit 12030 makes the imaging section 12031 image an image of the outside of the vehicle, and receives the imaged image. On the basis of the received image, the outside-vehicle information detecting unit 12030 may perform processing of detecting an object such as a human, a vehicle, an obstacle, a sign, a character on a road surface, or the like, or processing of detecting a distance thereto.

The imaging section 12031 is an optical sensor that receives light, and which outputs an electric signal corresponding to a received light amount of the light. The imaging section 12031 can output the electric signal as an image, or can output the electric signal as information about a measured distance. In addition, the light received by the imaging section 12031 may be visible light, or may be invisible light such as infrared rays or the like.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automated driving, which makes the vehicle to travel automatedly without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

In addition, the microcomputer 12051 can output a control command to the body system control unit 12020 on the basis of the information about the outside of the vehicle which information is obtained by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound and an image to an output device capable of visually or auditorily notifying information to an occupant of the vehicle or the outside of the vehicle. In the example of FIG. 43, an audio speaker 12061, a display section 12062, and an instrument panel 12063 are illustrated as the output device. The display section 12062 may, for example, include at least one of an on-board display and a head-up display.

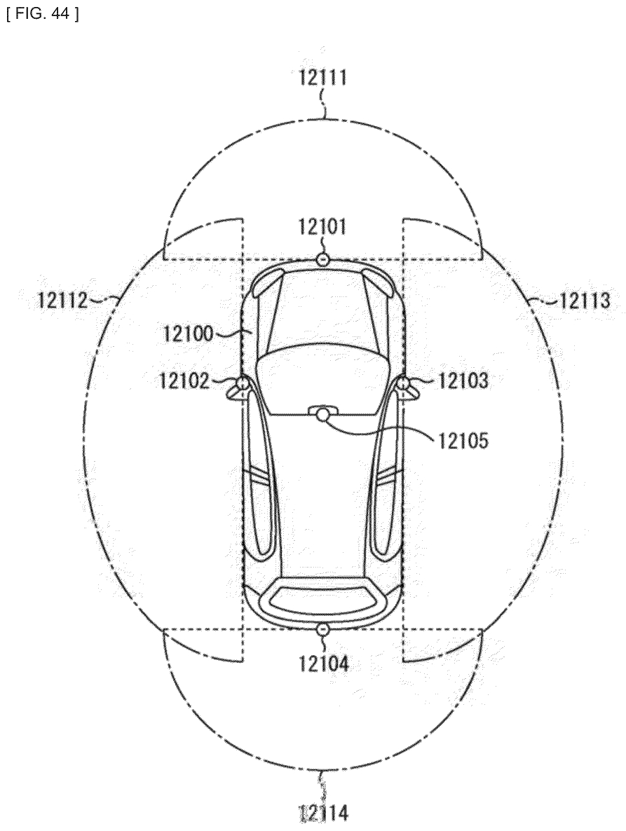

FIG. 44 is a diagram depicting an example of the installation position of the imaging section 12031.

In FIG. 44, the imaging section 12031 includes imaging sections 12101, 12102, 12103, 12104, and 12105.

The imaging sections 12101, 12102, 12103, 12104, and 12105 are, for example, disposed at positions on a front nose, sideview mirrors, a rear bumper, and a back door of the vehicle 12100 as well as a position on an upper portion of a windshield within the interior of the vehicle. The imaging section 12101 provided to the front nose and the imaging section 12105 provided to the upper portion of the windshield within the interior of the vehicle obtain mainly an image of the front of the vehicle 12100. The imaging sections 12102 and 12103 provided to the sideview mirrors obtain mainly an image of the sides of the vehicle 12100. The imaging section 12104 provided to the rear bumper or the back door obtains mainly an image of the rear of the vehicle 12100. The imaging section 12105 provided to the upper portion of the windshield within the interior of the vehicle is used mainly to detect a preceding vehicle, a pedestrian, an obstacle, a signal, a traffic sign, a lane, or the like.

Incidentally, FIG. 44 depicts an example of photographing ranges of the imaging sections 12101 to 12104. An imaging range 12111 represents the imaging range of the imaging section 12101 provided to the front nose. Imaging ranges 12112 and 12113 respectively represent the imaging ranges of the imaging sections 12102 and 12103 provided to the sideview mirrors. An imaging range 12114 represents the imaging range of the imaging section 12104 provided to the rear bumper or the back door. A bird's-eye image of the vehicle 12100 as viewed from above is obtained by superimposing image data imaged by the imaging sections 12101 to 12104, for example.

At least one of the imaging sections 12101 to 12104 may have a function of obtaining distance information. For example, at least one of the imaging sections 12101 to 12104 may be a stereo camera constituted of a plurality of imaging elements, or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Further, the microcomputer 12051 can set a following distance to be maintained in front of a preceding vehicle in advance, and perform automatic brake control (including following stop control), automatic acceleration control (including following start control), or the like. It is thus possible to perform cooperative control intended for automated driving that makes the vehicle travel automatedly without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether or not there is a pedestrian in imaged images of the imaging sections 12101 to 12104. Such recognition of a pedestrian is, for example, performed by a procedure of extracting characteristic points in the imaged images of the imaging sections 12101 to 12104 as infrared cameras and a procedure of determining whether or not it is the pedestrian by performing pattern matching processing on a series of characteristic points representing the contour of the object. When the microcomputer 12051 determines that there is a pedestrian in the imaged images of the imaging sections 12101 to 12104, and thus recognizes the pedestrian, the sound/image output section 12052 controls the display section 12062 so that a square contour line for emphasis is displayed so as to be superimposed on the recognized pedestrian. The sound/image output section 12052 may also control the display section 12062 so that an icon or the like representing the pedestrian is displayed at a desired position.

One example of the mobile body control system to which the technology according to the present disclosure may be applied has been described above. The technology according to the present disclosure is appliable to the imaging section 12031 among the configurations described above. Specifically, the imaging device (e.g., the imaging device 1) according to any of the embodiment described above and the modification examples thereof is applicable to the imaging section 12031. Applying the technology according to the present disclosure to the imaging section 12031 makes it possible to obtain a high-definition shot image with less noise. This makes it possible to perform highly accurate control with use of the shot image in the mobile body control system.

Although the present disclosure has been described with reference to the embodiment, the modification examples 1 to 13, the application examples, and the practical application examples, the present technology is not limited to the embodiment and the like described above, and may be modified in a variety of ways. Fore example, the modification examples 1 to 13 described above have been described as modification examples of the embodiment described above; however, it is possible to combine configurations of the respective modification examples as appropriate.

It is to be noted that the effects described herein are merely illustrative and non-limiting, and other effects may be provided.

It is to be noted that the present disclosure may have the following configurations. According to the present technology having the following configurations, a plurality of color filters is provided one for each of a plurality of pixels, a gap section is provided between the respective color filters, and a light-blocking section is formed at a bottom of the gap section. Accordingly, incident light is reflected at an interface between side surfaces of the color filters and the gap section, and absorption in the light-blocking section is reduced. Further, a first protective film that covers top surfaces and the side surfaces of the plurality of color filters is provided, which suppresses discoloration of the color filters. This makes it possible to reduce occurrence of color mixture while improving sensitivity.
(1)

An imaging device including:
a semiconductor substrate having a first surface and a second surface that are opposed to each other, and including a plurality of pixels and a plurality of photoelectric converters, the plurality of pixels disposed in a matrix, and the plurality of photoelectric converters that generates, through photoelectric conversion, an electric charge corresponding to an amount of received light incident from a subject without passing through an on-chip lens for each of the pixels;
a plurality of color filters provided one for each of the plurality of pixels on side of the first surface;
a first protective film that covers top surfaces and side surfaces of the plurality of color filters;
a gap section provided between the plurality of respective color filters; and
a light-blocking section provided at a bottom of the gap section.
(2)

The imaging device according to (1), in which the first protective film has a refractive index lower than a refractive index of the plurality of color filters.
(3)

The imaging device according to (2), in which a thickness of the first protective film that covers the top surfaces of the plurality of color filters is λ/4n with respect to a wavelength λ to be detected and a refractive index n of the first protective film.
(4)

The imaging device according to (2) or (3), in which the first protective film that covers the top surfaces of the plurality of color filters has a thickness larger than a thickness of the first protective film that covers the side surfaces of the plurality of color filters.
(5)

The imaging device according to any one of (1) to (4), in which the light-blocking section has a top surface positioned at a height less than or equal to ½ of a height of each of the plurality of color filters.
(6)

The imaging device according to any one of (1) to (5), in which a portion of the light-blocking section is embedded in the semiconductor substrate.
(7)

The imaging device according to any one of (1) to (6), further including an adhesion layer including an organic material between the first surface of the semiconductor substrate and the plurality of color filters.
(8)

The imaging device according to any one of (1) to (7), in which the plurality of color filters has an overhang portion partially extending toward a bottom of the light-blocking section.
(9)

The imaging device according to any one of (1) to (8), in which
the plurality of pixels includes a first pixel and a second pixel that detect wavelengths different from each other,
the first pixel and the second pixel are respectively provided with a first color filter and a second color filter as the plurality of color filters, the first color filter and the second color filter that allow wavelengths different from each other to selectively pass therethrough, and
the light-blocking section is provided only between the first color filter and the second color filter adjacent to each other.
(10)

The imaging device according to any one of (1) to (8), in which
the plurality of pixels includes a first pixel and a second pixel that detect wavelengths different from each other,
the first pixel and the second pixel are respectively provided with a first color filter and a second color filter as the plurality of color filters, the first color filter and the second color filter that allow wavelengths different from each other to selectively pass therethrough,
the gap section is provided only between the first pixel and the second pixel adjacent to each other, and
the first color filter and the second color filter are respectively provided continuously for a plurality of the first pixels adjacent to each other and a plurality of the second pixels adjacent to each other.
(11)

The imaging device according to any one of (1) to (10), in which the plurality of color filters each has a substantially rectangular cross-sectional shape.
(12)

The imaging device according to any one of (1) to (10), in which a cross-sectional shape of each of the plurality of color filters has a top surface that is a curved surface.
(13)

The imaging device according to any one of (1) to (12), in which the plurality of color filters includes a plurality of layers stacked, the plurality of layers having transmission spectra different from each other.
(14)

The imaging device according to any one of (1) to (13), in which
the plurality of pixels includes an image-plane phase-difference pixel that detects a phase difference, and
the image-plane phase-difference pixel includes a plurality of photoelectric converters disposed side by side, and in the image-plane phase-difference pixel, the color filter is provided over the plurality of photoelectric converters.
(15)

The imaging device according to any one of (1) to (14), in which each of the plurality of color filters is provided at a position shifted toward an optical center of a pixel array section including the plurality of pixels disposed in a matrix with respect to each of the plurality of pixels in accordance with a position of the pixel array section.
(16)

The imaging device according to (15), in which shift amounts of the plurality of color filters provided one for each of the plurality of pixels disposed in a matrix differ substantially concentrically from the optical center of the pixel array section.
(17)

The imaging device according to any one of (1) to (16), in which each of the plurality of color filters is provided to be shifted for each image height in accordance with an incident angle of light to enter each of the plurality of pixels disposed in a matrix.
(18)

The imaging device according to any one of (14) to (17), in which an on-chip lens is further provided on the color filter provided for the image-plane phase-difference pixel.
(19)

The imaging device according to any one of (1) to (18), in which the plurality of pixels is disposed with a pitch of 1.5 μm or less.
(20)

The imaging device according to any one of (1) to (19), in which a second protective film is further provided continuously on the plurality of color filters, and the gap section is blocked by the second protective film.

This application claims the priority on the basis of Japanese Patent Application No. 2021-150995 filed on Sep. 16, 2021 with Japan Patent Office, the entire contents of which are incorporated in this application by reference.

It should be understood by those skilled in the art that various modifications, combinations, sub-combinations, and alterations may occur depending on design requirements and other factors insofar as they are within the scope of the appended claims or the equivalents thereof.

1. An imaging device comprising:
a semiconductor substrate having a first surface and a second surface that are opposed to each other, and including a plurality of pixels and a plurality of photoelectric converters, the plurality of pixels disposed in a matrix, and the plurality of photoelectric converters that generates, through photoelectric conversion, an electric charge corresponding to an amount of received light incident from a subject without passing through an on-chip lens for each of the pixels;
a plurality of color filters provided one for each of the plurality of pixels on side of the first surface;
a first protective film that covers top surfaces and side surfaces of the plurality of color filters;
a gap section provided between the plurality of respective color filters; and
a light-blocking section provided at a bottom of the gap section.

2. The imaging device according to claim 1, wherein the first protective film has a refractive index lower than a refractive index of the plurality of color filters.

3. The imaging device according to claim 2, wherein a thickness of the first protective film that covers the top surfaces of the plurality of color filters is λ/4n with respect to a wavelength λ to be detected and a refractive index n of the first protective film.

4. The imaging device according to claim 2, wherein the first protective film that covers the top surfaces of the plurality of color filters has a thickness larger than a thickness of the first protective film that covers the side surfaces of the plurality of color filters.

5. The imaging device according to claim 1, wherein the light-blocking section has a top surface positioned at a height less than or equal to ½ of a height of each of the plurality of color filters.

6. The imaging device according to claim 1, wherein a portion of the light-blocking section is embedded in the semiconductor substrate.

7. The imaging device according to claim 1, further comprising an adhesion layer including an organic material between the first surface of the semiconductor substrate and the plurality of color filters.

8. The imaging device according to claim 1, wherein the plurality of color filters has an overhang portion partially extending toward a bottom of the light-blocking section.

9. The imaging device according to claim 1, wherein
the plurality of pixels includes a first pixel and a second pixel that detect wavelengths different from each other,
the first pixel and the second pixel are respectively provided with a first color filter and a second color filter as the plurality of color filters, the first color filter and the second color filter that allow wavelengths different from each other to selectively pass therethrough, and
the light-blocking section is provided only between the first color filter and the second color filter adjacent to each other.

10. The imaging device according to claim 1, wherein
the plurality of pixels includes a first pixel and a second pixel that detect wavelengths different from each other,
the first pixel and the second pixel are respectively provided with a first color filter and a second color filter as the plurality of color filters, the first color filter and the second color filter that allow wavelengths different from each other to selectively pass therethrough,
the gap section is provided only between the first pixel and the second pixel adjacent to each other, and
the first color filter and the second color filter are respectively provided continuously for a plurality of the first pixels adjacent to each other and a plurality of the second pixels adjacent to each other.

11. The imaging device according to claim 1, wherein the plurality of color filters each has a substantially rectangular cross-sectional shape.

12. The imaging device according to claim 1, wherein a cross-sectional shape of each of the plurality of color filters has a top surface that is a curved surface.

13. The imaging device according to claim 1, wherein the plurality of color filters includes a plurality of layers stacked, the plurality of layers having transmission spectra different from each other.

14. The imaging device according to claim 1, wherein
the plurality of pixels includes an image-plane phase-difference pixel that detects a phase difference, and
the image-plane phase-difference pixel includes a plurality of photoelectric converters disposed side by side, and in the image-plane phase-difference pixel, the color filter is provided over the plurality of photoelectric converters.

15. The imaging device according to claim 1, wherein each of the plurality of color filters is provided at a position shifted toward an optical center of a pixel array section including the plurality of pixels disposed in a matrix with respect to each of the plurality of pixels in accordance with a position of the pixel array section.

16. The imaging device according to claim 15, wherein shift amounts of the plurality of color filters provided one for each of the plurality of pixels disposed in a matrix differ substantially concentrically from the optical center of the pixel array section.

17. The imaging device according to claim 1, wherein each of the plurality of color filters is provided to be shifted for each image height in accordance with an incident angle of light to enter each of the plurality of pixels disposed in a matrix.

18. The imaging device according to claim 14, wherein an on-chip lens is further provided on the color filter provided for the image-plane phase-difference pixel.

19. The imaging device according to claim 1, wherein the plurality of pixels is disposed with a pitch of 1.5 μm or less.

20. The imaging device according to claim 1, wherein a second protective film is further provided continuously on the plurality of color filters, and the gap section is blocked by the second protective film.
